(19) United States
(12) Patent Application Publication
(10) Pub. No.: US 2026/0089990 A1
(43) Pub. Date: Mar. 26, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Shunta MURAI, Kanazawa Ishikawa (JP); Tomoko MATSUDAI, Shibuya Tokyo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/073,281

(22) Filed: Mar. 7, 2025

(30) Foreign Application Priority Data
Sep. 23, 2024 (JP) 2024-164675

(51) Int. Cl. H10D 12/00; H10D 84/00

(52) U.S. Cl. CPC H10D 12/415; H10D 12/481; H10D 84/161

(57) ABSTRACT

A semiconductor device according to an embodiment includes a transistor region, a diode region, and a termination region surrounding the transistor region and the diode region. The transistor region includes first trenches and first conductive layers in the first trenches. The diode region includes second trenches and second conductive layers in the second trenches. The termination region includes a third trench, a first electrode pad electrically connected to the first conductive layers in at least a part of the first trench, and a second electrode pad electrically connected to a second conductive layer in a second trench closest to the third trench among the second trenches.

### CROSS-REFERENCE TO RELATED APPLICATION

This application is based upon and claims the benefit of priority from Japanese Patent Application No. 2024-164675, filed on Sep. 23, 2024, the entire contents of which are incorporated herein by reference.

### FIELD

Embodiments described herein relate generally to a semiconductor device.

### BACKGROUND

An example of a power semiconductor device is an insulated gate bipolar transistor (IGBT). In the IGBT, for example, a p type collector region, an n type drift region, and a p type base region are provided on a collector electrode. A gate electrode is provided in a trench penetrating the p type base region and reaching the n type drift region with a gate insulating film interposed therebetween. Furthermore, an n type emitter region connected to an emitter electrode is provided in a region adjacent to a trench of a surface of the p type base region.

In recent years, a reverse-conducting IGBT (RC-IGBT) in which an IGBT and a freewheeling diode are formed on the same semiconductor chip has been widely developed and put into production. The RC-IGBT is used, for example, as a switching element of an inverter circuit. The freewheeling diode has a function of causing a current to flow in a direction opposite to an ON current of the IGBT. Forming the IGBT and the freewheeling diode on the same semiconductor chip has many advantages such as reduction in chip size by sharing of a termination region and dispersion of heat generating portions.

For example, when the RC-IGBT is used as a switching element of an inverter circuit, two RC-IGBTs are provided in series on a high side and a low side, respectively. For example, when a reverse recovery loss (Err) of the freewheeling diode of one RC-IGBT increases, a turn-on loss (Eon) of the IGBT of the other RC-IGBT increases, and a loss of the inverter circuit increases. Therefore, it is desired to reduce the reverse recovery loss (Err) of the freewheeling diode of the RC-IGBT.

### BRIEF DESCRIPTION OF THE DRAWINGS

FIG. 1 is a schematic diagram of a semiconductor device according to a first embodiment;

FIG. 2 is a schematic cross-sectional view of a part of the semiconductor device according to the first embodiment;

FIG. 3 is a schematic top view of a part of the semiconductor device according to the first embodiment;

FIG. 4 is a schematic cross-sectional view of a part of the semiconductor device according to the first embodiment;

FIG. 5 is a schematic top view of a part of the semiconductor device according to the first embodiment;

FIG. 6 is a schematic top view of a part of the semiconductor device according to the first embodiment;

FIG. 7 is a schematic cross-sectional view of a part of a semiconductor device according to a comparative example;

FIG. 8 is an explanatory diagram of a problem of the semiconductor device according to the comparative example;

FIG. 9 is an explanatory diagram of a problem of the semiconductor device according to the comparative example;

FIG. 10 is an explanatory diagram of functions and effects of the semiconductor device of the first embodiment;

FIG. 11 is an explanatory diagram of functions and effects of the semiconductor device of the first embodiment;

FIG. 12 is a schematic cross-sectional view of a part of a semiconductor device according to a first modified example of the first embodiment;

FIG. 13 is a schematic cross-sectional view of a part of a semiconductor device according to a second modified example of the first embodiment;

FIG. 14 is a schematic cross-sectional view of a part of a semiconductor device according to a third modified example of the first embodiment;

FIG. 15 is a schematic cross-sectional view of a part of the semiconductor device according to a second embodiment;

FIG. 16 is a schematic top view of a part of the semiconductor device according to the second embodiment;

FIG. 17 is an explanatory diagram of functions and effects of the semiconductor device of the second embodiment;

FIG. 18 is a schematic cross-sectional view of a part of a semiconductor device according to a first modified example of the second embodiment;

FIG. 19 is a schematic cross-sectional view of a part of a semiconductor device according to a second modified example of the second embodiment;

FIG. 20 is a schematic cross-sectional view of a part of a semiconductor device according to a third modified example of the second embodiment;

FIG. 21 is a schematic cross-sectional view of a part of the semiconductor device according to a third embodiment; and

FIG. 22 is a schematic cross-sectional view of a part of a semiconductor device according to a modified example of the third embodiment.

### DETAILED DESCRIPTION

A semiconductor device according to an embodiment includes: a transistor region; a diode region; and a termination region surrounding the transistor region and the diode region, the diode region being provided between the termination region and the transistor region, wherein the transistor region includes: a semiconductor layer having a first face and a second face opposed to the first face; a first semiconductor region of a first conductivity type, the first semiconductor region being provided in the semiconductor layer; a second semiconductor region of a second conductivity type, the second semiconductor region being provided in the semiconductor layer and between the first semiconductor region and the first face; a third semiconductor region of a first conductivity type, the third semiconductor region being provided in the semiconductor layer and between the second semiconductor region and the first face; a fourth semiconductor region of a second conductivity type, the fourth semiconductor region being provided in the semiconductor layer and between the third semiconductor region and the first face; a plurality of first trenches provided on a side of the first face in the semiconductor layer, the first trenches extending in a first direction parallel to the first face, the first trenches being disposed repeatedly in a second direction perpendicular to the first direction and parallel to the first face, the first trenches being in contact with the second semiconductor region, the third semiconductor region, and the fourth semiconductor region; a first conductive layer provided in each of the first trenches; a first insulating film provided between the first conductive layer and the semiconductor layer; a first electrode provided on a side of the first face with respect to the semiconductor layer, the first electrode being in contact with the fourth semiconductor region; and a second electrode provided on a side of the second face with respect to the semiconductor layer, the second electrode being in contact with the first semiconductor region, wherein the diode region includes: the semiconductor layer; the second semiconductor region; a fifth semiconductor region of a second conductivity type, the fifth semiconductor region being provided in the semiconductor layer, the fifth semiconductor region being provided between the second semiconductor region and the second face, the fifth semiconductor region having a second conductivity type impurity concentration higher than a second conductivity type impurity concentration of the second semiconductor region; a sixth semiconductor region of a first conductivity type provided in the semiconductor layer, the sixth semiconductor region being provided between the second semiconductor region and the first face; a plurality of second trenches provided on a side of the first face in the semiconductor layer, the second trenches extending in the first direction, the second trenches being disposed repeatedly in the second direction, the second trenches being in contact with the second semiconductor region and the sixth semiconductor region; a second conductive layer provided in each of the second trenches; a second insulating film provided between the second conductive layer and the semiconductor layer; the first electrode electrically connected to the sixth semiconductor region; and the second electrode in contact with the fifth semiconductor region, and wherein the termination region includes: the semiconductor layer; the second semiconductor region; a seventh semiconductor region of a first conductivity type, the seventh semiconductor region being provided in the semiconductor layer, the seventh semiconductor region being provided between the second semiconductor region and the first face, the seventh semiconductor region being electrically connected to the first electrode; at least one third trench provided on a side of the first face in the semiconductor layer, the at least one third trench being provided between the seventh semiconductor region and the first face, the at least one third trench extending in the first direction, the at least one third trench being in contact with the seventh semiconductor region; a third conductive layer provided in each of the at least one third trench; a third insulating film provided between the third conductive layer and the semiconductor layer; the first electrode; the second electrode; a first electrode pad provided on a side of the first face with respect to the semiconductor layer, the first electrode pad being electrically connected to the first conductive layer provided in each of at least a part of the plurality of first trenches; and a second electrode pad provided on a side of the first face with respect to the semiconductor layer, the second electrode pad being electrically connected to the second conductive layer provided in a second trench closest to the at least one third trench among the plurality of second trenches.

Hereinafter, embodiments of the present disclosure will be described with reference to the drawings. In the following description, the same or similar members and the like are denoted by the same reference numerals, and the description of the members and the like once described shall be appropriately omitted.

In the present specification, when there are notations of n⁺ type, n type, and n⁻ type, it means that an n type impurity concentration decreases in the order of n⁺ type, n type, and n⁻ type. In addition, when there are notations of p⁺ type, p type, and p⁻ type, it means that the p type impurity concentration decreases in the order of p⁺ type, p type, and p⁻ type.

In the present specification, the n type impurity concentration does not indicate an actual n type impurity concentration, but indicates an effective n type impurity concentration after compensation. Similarly, the p type impurity concentration does not indicate an actual p type impurity concentration, but indicates an effective p type impurity concentration after compensation. For example, when the actual n type impurity concentration is higher than the actual p type impurity concentration, the concentration obtained by subtracting the actual p type impurity concentration from the actual n type impurity concentration is defined as the n type impurity concentration. The same applies to the p type impurity concentration.

In the present specification, a distribution and an absolute value of an impurity concentration of semiconductor region can be measured using secondary ion mass spectrometry (SIMS), for example. In addition, a relative magnitude relationship between impurity concentrations of two semiconductor regions can be determined using scanning capacitance microscopy (SCM), for example. In addition, a distribution and an absolute value of an impurity concentration can be measured using a spreading resistance analysis (SRA), for example. In the SCM and the SRA, a relative magnitude relationship and an absolute value of the carrier concentration of a semiconductor region are obtained. By assuming an activation rate of impurities, it is possible to obtain the relative magnitude relationship between the impurity concentrations of the two semiconductor regions, the distribution of the impurity concentration, and the absolute value of the impurity concentration from the measurement results of the SCM and the SRA.

The impurity concentration of the semiconductor region is represented by the impurity concentration near the center of the semiconductor region unless otherwise specified in the specification.

### First Embodiment

A semiconductor device according to a first embodiment includes: a transistor region; a diode region; and a termination region surrounding the transistor region and the diode region, the diode region being provided between the termination region and the transistor region. The transistor region includes: a semiconductor layer having a first face and a second face opposed to the first face; a first semiconductor region of a first conductivity type, the first semiconductor region being provided in the semiconductor layer; a second semiconductor region of a second conductivity type, the second semiconductor region being provided in the semiconductor layer and between the first semiconductor region and the first face; a third semiconductor region of a first conductivity type, the third semiconductor region being provided in the semiconductor layer and between the second semiconductor region and the first face; a fourth semiconductor region of a second conductivity type, the fourth semiconductor region being provided in the semiconductor layer and between the third semiconductor region and the first face; a plurality of first trenches provided on a side of the first face in the semiconductor layer, the first trenches extending in a first direction parallel to the first face, the first trenches being disposed repeatedly in a second direction perpendicular to the first direction and parallel to the first face, the first trenches being in contact with the second semiconductor region, the third semiconductor region, and the fourth semiconductor region; a first conductive layer provided in each of the first trenches; a first insulating film provided between the first conductive layer and the semiconductor layer; a first electrode provided on a side of the first face with respect to the semiconductor layer, the first electrode being in contact with the fourth semiconductor region; and a second electrode provided on a side of the second face with respect to the semiconductor layer, the second electrode being in contact with the first semiconductor region. The diode region includes: the semiconductor layer; the second semiconductor region; a fifth semiconductor region of a second conductivity type, the fifth semiconductor region being provided in the semiconductor layer, the fifth semiconductor region being provided between the second semiconductor region and the second face, the fifth semiconductor region having a second conductivity type impurity concentration higher than a second conductivity type impurity concentration of the second semiconductor region; a sixth semiconductor region of a first conductivity type provided in the semiconductor layer, the sixth semiconductor region being provided between the second semiconductor region and the first face; a plurality of second trenches provided on a side of the first face in the semiconductor layer, the second trenches extending in the first direction, the second trenches being disposed repeatedly in the second direction, the second trenches being in contact with the second semiconductor region and the sixth semiconductor region; a second conductive layer provided in each of the second trenches; a second insulating film provided between the second conductive layer and the semiconductor layer; the first electrode electrically connected to the sixth semiconductor region; and the second electrode in contact with the fifth semiconductor region. The termination region includes: the semiconductor layer; the second semiconductor region; a seventh semiconductor region of a first conductivity type, the seventh semiconductor region being provided in the semiconductor layer, the seventh semiconductor region being provided between the second semiconductor region and the first face, the seventh semiconductor region being electrically connected to the first electrode; a third trench provided on a side of the first face in the semiconductor layer, the third trench being provided between the seventh semiconductor region and the first face, the third trench extending in the first direction, the third trench being in contact with the seventh semiconductor region; a third conductive layer provided in the third trench; a third insulating film provided between the third conductive layer and the semiconductor layer; the first electrode; the second electrode; a first electrode pad provided on a side of the first face with respect to the semiconductor layer, the first electrode pad being electrically connected to the first conductive layers that are provided in at least a part of the plurality of first trenches; and a second electrode pad provided on a side of the first face with respect to the semiconductor layer, the second electrode pad being electrically connected to the second conductive layer provided in a second trench closest to the third trench among the plurality of second trenches.

The semiconductor device of the first embodiment is an RC-IGBT 100 in which an IGBT and a freewheeling diode are formed on the same semiconductor chip. The RC-IGBT 100 includes a trench gate type IGBT including a gate electrode in a trench formed in a semiconductor layer. Hereinafter, a case where the first conductivity type is p type and the second conductivity type is n type will be described as an example.

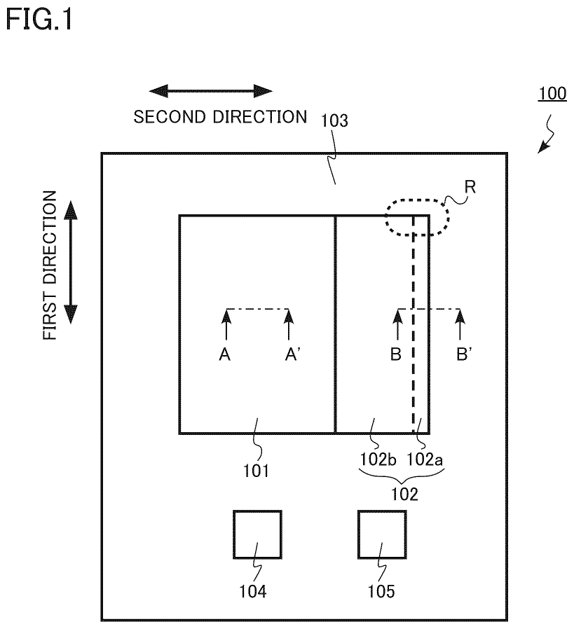

FIG. 1 is a schematic diagram of a semiconductor device according to the first embodiment.

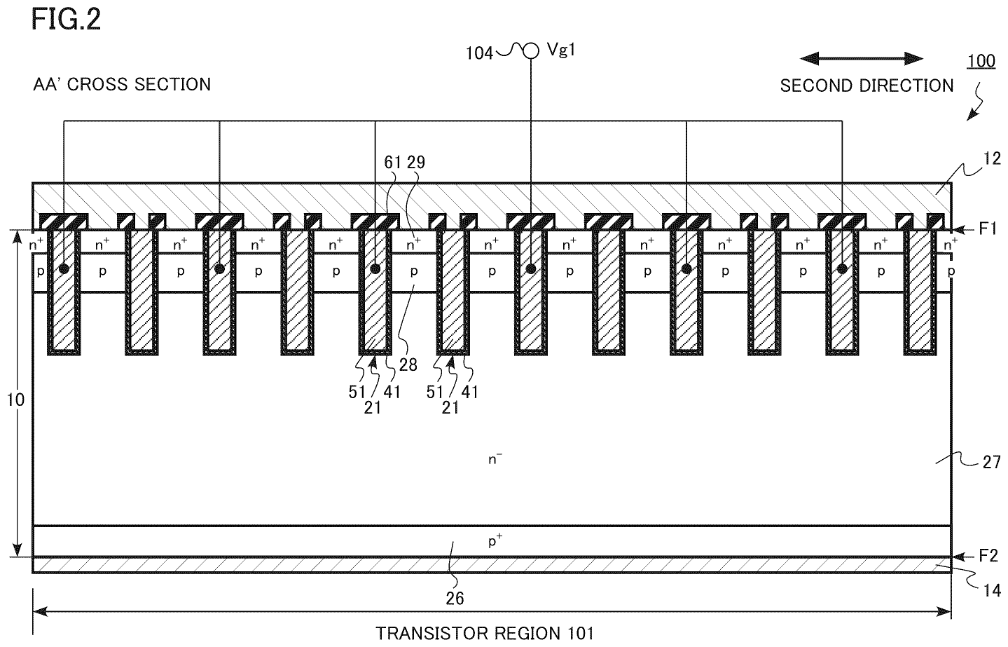

FIG. 2 is a schematic cross-sectional view of a part of the semiconductor device according to the first embodiment. FIG. 2 is a cross section taken along line AA′ in FIG. 1.

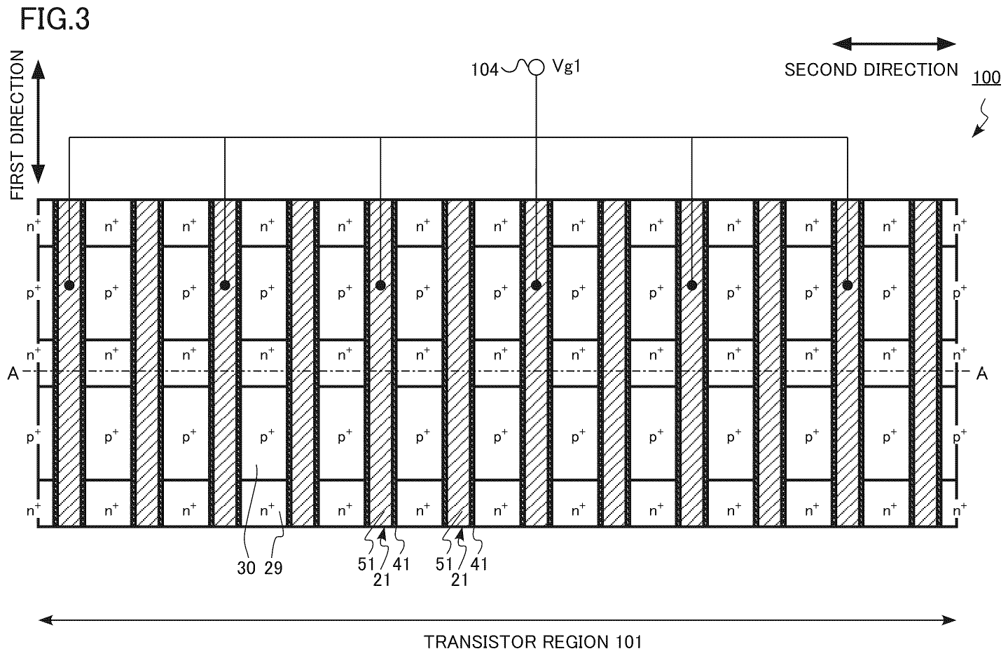

FIG. 3 is a schematic top view of a part of the semiconductor device according to the first embodiment. FIG. 3 is a top view of a first face F1. FIG. 2 is a cross section taken along line AA′ in FIG. 3.

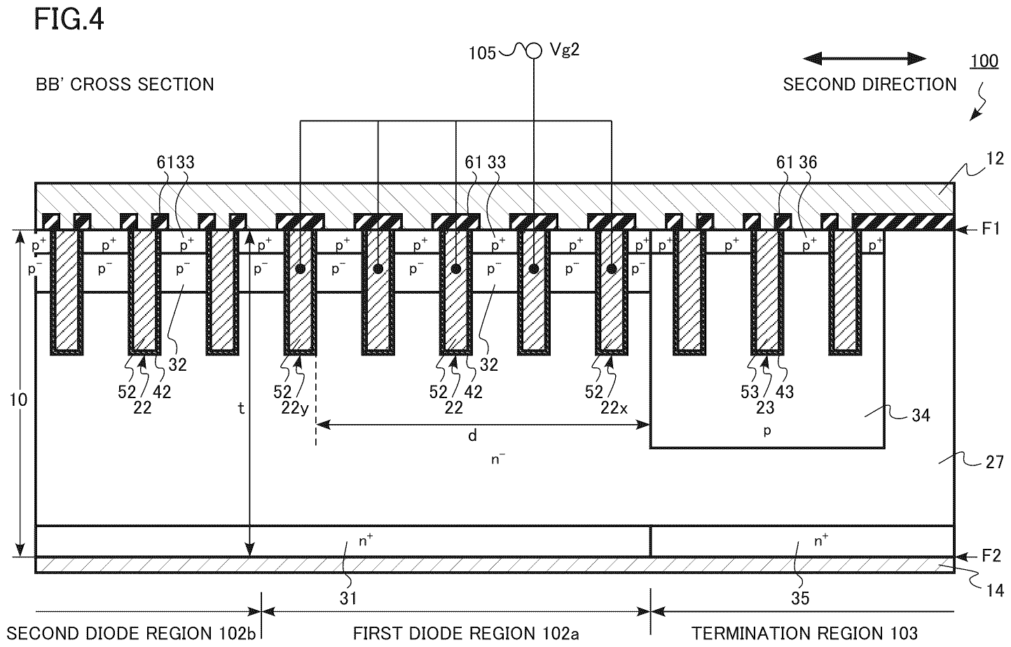

FIG. 4 is a schematic cross-sectional view of a part of the semiconductor device according to the first embodiment. FIG. 4 is a cross section taken along line BB′ in FIG. 1.

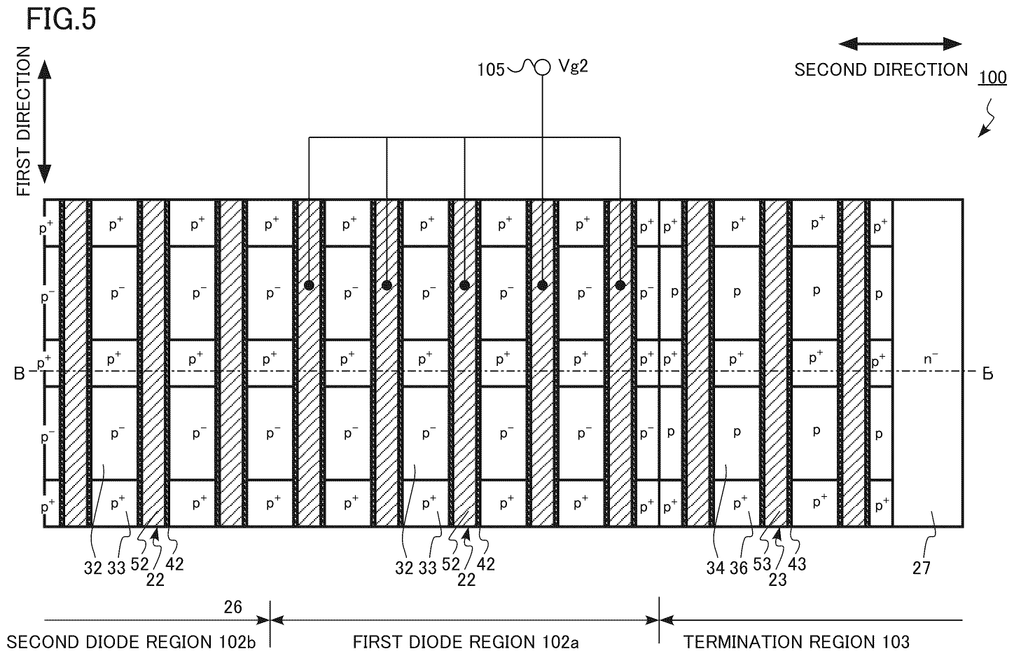

FIG. 5 is a schematic top view of a part of the semiconductor device according to the first embodiment. FIG. 5 is a top view of the first face F1. FIG. 4 is a cross section taken along line BB′ in FIG. 5.

As illustrated in FIG. 1, the RC-IGBT 100 includes a transistor region 101, a diode region 102, and a termination region 103. The termination region 103 surrounds the transistor region 101 and the diode region 102. The diode region 102 is provided between the transistor region 101 and the termination region 103.

The diode region 102 includes a first diode region 102a (first region) and a second diode region 102b (second region). The second diode region 102b is provided between the first diode region 102a and the transistor region 101.

The termination region 103 relaxes an intensity of an electric field applied to a termination portion of a pn junction between the transistor region 101 and the diode region 102 in a case where the RC-IGBT 100 is in an OFF state. The termination region 103 has a function of improving a dielectric breakdown voltage of the RC-IGBT 100.

The transistor region 101 operates as an IGBT. The diode region 102 operates as a freewheeling diode. The freewheeling diode is, for example, a fast recovery diode (FRD).

The RC-IGBT 100 of the first embodiment includes a semiconductor layer 10, an upper electrode 12 (first electrode), a lower electrode 14 (second electrode), a first insulating film 41, a second insulating film 42, a third insulating film 43, a first conductive layer 51, a second conductive layer 52, a third conductive layer 53, an interlayer insulating layer 61, a first gate electrode pad 104 (first electrode pad), and a second gate electrode pad 105 (second electrode pad).

In the semiconductor layer 10, a first trench 21, a second trench 22, a third trench 23, a p⁺ type collector region 26 (first semiconductor region), an n⁻ type drift region 27 (second semiconductor region), a p type cell base region 28 (third semiconductor region), an n⁺ type cell emitter region 29 (fourth semiconductor region), a p⁺ type cell contact region 30, an n⁺ type cathode region 31 (fifth semiconductor region), a p⁻ type anode region 32 (sixth semiconductor region), a p⁺ type diode contact region 33, a p type guard ring region 34 (seventh semiconductor region), an n⁺ type terminal cathode region 35 (eighth semiconductor region), and a p⁺ type guard ring contact region 36 are provided.

The semiconductor layer 10 has the first face F1 and a second face F2 facing the first face F1. The semiconductor layer 10 is, for example, single crystal silicon. A thickness of the semiconductor layer 10 is, for example, equal to or more than 40 μm and equal to or less than 700 μm.

In the present specification, one direction parallel to the first face F1 is referred to as a first direction. Further, a direction parallel to the first face F1 and perpendicular to the first direction is referred to as a second direction. In addition, in the present specification, “depth” is defined as a distance in a direction toward the second face F2 with respect to the first face F1.

The transistor region 101 includes the semiconductor layer 10, the upper electrode 12 (first electrode), the lower electrode 14 (second electrode), the first insulating film 41, the first conductive layer 51, and the interlayer insulating layer 61.

In the semiconductor layer 10 of the transistor region 101, the first trench 21, the collector region 26 (first semiconductor region), the drift region 27 (second semiconductor region), the cell base region 28 (third semiconductor region), the cell emitter region 29 (fourth semiconductor region), and the cell contact region 30 are provided.

The upper electrode 12 is provided on a side of the first face F1 of the semiconductor layer 10. At least a part of the upper electrode 12 is in contact with the first face F1 of the semiconductor layer 10.

The upper electrode 12 functions as an emitter electrode of the IGBT in the transistor region 101. The upper electrode 12 is, for example, metal.

The upper electrode 12 is in contact with the cell emitter region 29. The upper electrode 12 is electrically connected to the cell emitter region 29.

The upper electrode 12 is in contact with the cell contact region 30. The upper electrode 12 is electrically connected to the cell contact region 30. The upper electrode 12 is electrically connected to the cell base region 28 via the cell contact region 30.

The lower electrode 14 is provided on a side of the second face F2 of the semiconductor layer 10. At least a part of the lower electrode 14 is in contact with the second face F2 of the semiconductor layer 10.

The lower electrode 14 functions as a collector electrode of the IGBT in the transistor region 101. The lower electrode 14 is, for example, metal.

The lower electrode 14 is in contact with the collector region 26 in the transistor region 101. The lower electrode 14 is electrically connected to the collector region 26 in the transistor region 101.

The collector region 26 is a p⁺ type semiconductor region. The collector region 26 is in contact with the second face F2. The collector region 26 is electrically connected to the lower electrode 14. The collector region 26 is in contact with the lower electrode 14. The collector region 26 serves as a supply source of holes when the IGBT is in an ON state.

The drift region 27 is an n⁻ type semiconductor region. The drift region 27 is provided between the collector region 26 and the first face F1.

The drift region 27 serves as a path of an ON current in a case where the IGBT is in the ON state. The drift region 27 has a function of being depleted in a case where the IGBT is in the OFF state and maintaining a breakdown voltage of the IGBT.

The cell base region 28 is a p type semiconductor region. The cell base region 28 is provided between the drift region 27 and the first face F1. The drift region 27 is sandwiched between the cell base region 28 and the collector region 26.

A depth of the cell base region 28 is, for example, equal to or less than 5 μm. In a region of the cell base region 28 facing the first conductive layer 51 to which a first gate voltage Vg1 is applied, an n type inversion layer is formed in a case where the IGBT is in the ON state. The cell base region 28 functions as a channel region of a transistor.

The cell emitter region 29 is an n⁺ type semiconductor region. The cell emitter region 29 is provided between the cell base region 28 and the first face F1. The cell emitter region 29 is in contact with the first insulating film 41.

The n type impurity concentration of the cell emitter region 29 is higher than the n type impurity concentration of the drift region 27.

The cell emitter region 29 is in contact with the upper electrode 12. The cell emitter region 29 is electrically connected to the upper electrode 12. The cell emitter region 29 serves as a supply source of electrons in a case where the transistor is in the ON state.

The cell contact region 30 is a p⁺ type semiconductor region. The cell contact region 30 is provided between the cell base region 28 and the first face F1. The cell contact region 30 is in contact with the upper electrode 12. The cell contact region 30 is electrically connected to the upper electrode 12.

A p type impurity concentration of the cell contact region 30 is higher than a p type impurity concentration of the cell base region 28.

The first trench 21 is provided on a side of the first face F1 of the semiconductor layer 10. The first trench 21 is a groove provided in the semiconductor layer 10. The first trench 21 is a part of the semiconductor layer 10.

As illustrated in FIG. 3, the first trench 21 extends in the first direction parallel to the first face F1 in the first face F1. The first trench 21 has a stripe shape. A plurality of the first trenches 21 are disposed repeatedly in the second direction perpendicular to the first direction.

The first trench 21 is in contact with the drift region 27, the cell base region 28, and the cell emitter region 29. The first trench 21 penetrates the cell base region 28 and reaches the drift region 27. A depth of the first trench 21 is, for example, equal to or less than 8 μm.

The first conductive layer 51 is provided in the first trench 21. The first conductive layer 51 is, for example, a semiconductor or a metal. The first conductive layer 51 is amorphous silicon or polycrystalline silicon, for example, containing n type impurities or p type impurities.

A part of the first conductive layer 51 is electrically connected to the first gate electrode pad 104. In FIGS. 2 and 3, the first conductive layer 51, illustrated such that the first gate voltage Vg1 is applied, is electrically connected to the first gate electrode pad 104.

A part of the first conductive layer 51 is electrically connected to the upper electrode 12. In FIG. 2, the first conductive layer 51 in contact with the upper electrode 12 is electrically connected to the upper electrode 12.

Hereinafter, the first trench 21 in which the first conductive layer 51 electrically connected to the first gate electrode pad 104 is provided is referred to as a first gate trench. In addition, the first trench 21 in which the first conductive layer 51 electrically connected to the upper electrode 12 is provided is referred to as a first dummy trench.

The first gate trenches and the first dummy trenches are disposed alternately one by one in the second direction. In the transistor region 101, a ratio of the first gate trenches to the first trenches 21 is 50%.

Note that the first dummy trench may not be provided in the transistor region 101, and a ratio of a number of the first gate trenches to a number of the first trenches 21 in the transistor region 101 is not limited to 50%, and may take other ratios.

The first insulating film 41 is provided between the first conductive layer 51 and the semiconductor layer 10. The first insulating film 41 is provided between the first conductive layer 51 and the drift region 27, between the first conductive layer 51 and the cell base region 28, and between the first conductive layer 51 and the cell emitter region 29. The first insulating film 41 is in contact with the drift region 27, the cell base region 28, and the cell emitter region 29. The first insulating film 41 is, for example, silicon oxide.

The interlayer insulating layer 61 is provided between the first conductive layer 51 and the upper electrode 12. The interlayer insulating layer 61 electrically separates a part of the first conductive layer 51 and the upper electrode 12, and electrically separates the first conductive layer 51 and the semiconductor layer 10. The interlayer insulating layer 61 is, for example, silicon oxide.

The diode region 102 includes the semiconductor layer 10, the upper electrode 12 (first electrode), the lower electrode 14 (second electrode), the second insulating film 42, the second conductive layer 52, and the interlayer insulating layer 61.

In the semiconductor layer 10 of the diode region 102, the second trench 22, the cathode region 31 (fifth semiconductor region), the drift region 27 (second semiconductor region), the anode region 32 (sixth semiconductor region), and the diode contact region 33 are provided.

The upper electrode 12 functions as an anode electrode of a diode in the diode region 102. The upper electrode 12 is in contact with the diode contact region 33. The upper electrode 12 is electrically connected to the diode contact region 33. The upper electrode 12 is electrically connected to the anode region 32 via the diode contact region 33. The upper electrode 12 may be in direct contact with the anode region 32. In this case, for example, the upper electrode 12 and the anode region 32 have a Schottky junction.

The lower electrode 14 functions as a cathode electrode of the diode in the diode region 102. The lower electrode 14 is in contact with the cathode region 31.

The cathode region 31 is an n⁺ type semiconductor region. The cathode region 31 is in contact with the second face F2. The cathode region 31 serves as a supply source of electrons in a case where the diode is in the ON state. The cathode region 31 is in contact with the lower electrode 14.

The drift region 27 is an n⁻ type semiconductor region. The drift region 27 is provided between the cathode region 31 and the first face F1. The n type impurity concentration of the drift region 27 is lower than the n type impurity concentration of the cathode region 31.

The drift region 27 serves as a path of an ON current in a case where the diode is in the ON state.

The anode region 32 is a p⁻ type semiconductor region. The anode region 32 is provided between the drift region 27 and the first face F1. The anode region 32 sandwiches the drift region 27 with the cathode region 31.

The anode region 32 serves as a supply source of holes in a case where the diode is in the ON state.

A p type impurity concentration of the anode region 32 is lower than the p type impurity concentration of the cell base region 28, for example. The p type impurity concentration of the anode region 32 may be the same as the p type impurity concentration of the cell base region 28, for example.

The p type impurity concentration of the anode region 32 is lower than a p type impurity concentration of the guard ring region 34, for example. A depth of the anode region 32 is the same as the depth of the cell base region 28, for example.

The diode contact region 33 is a p⁺ type semiconductor region. The diode contact region 33 is provided between the anode region 32 and the first face F1.

The diode contact region 33 is in contact with the upper electrode 12. The diode contact region 33 is electrically connected to the upper electrode 12.

A p type impurity concentration of the diode contact region 33 is higher than the p type impurity concentration of the anode region 32.

The second trench 22 is provided on a side of the first face F1 of the semiconductor layer 10. The second trench 22 is a groove provided in the semiconductor layer 10. The second trench 22 is a part of the semiconductor layer 10.

As illustrated in FIG. 5, the second trench 22 extends in the first direction parallel to the first face F1 in the first face F1. The second trench 22 has a stripe shape. A plurality of the second trenches 22 are disposed repeatedly in the second direction perpendicular to the first direction.

The second trench 22 is in contact with the drift region 27 and the anode region 32. The second trench 22 penetrates the anode region 32 and reaches the drift region 27. A depth of the second trench 22 is, for example, equal to or less than 8 μm.

The second conductive layer 52 is provided in the second trench 22. The second conductive layer 52 is, for example, a semiconductor or a metal. The second conductive layer 52 is amorphous silicon or polycrystalline silicon, for example, containing n type impurities or p type impurities.

At least a part of the second conductive layer 52 is electrically connected to the second gate electrode pad 105. In FIGS. 4 and 5, the second conductive layer 52, illustrated such that the second gate voltage Vg2 is applied, is electrically connected to the second gate electrode pad 105.

In the second direction, the second conductive layer 52 provided in a second trench 22x closest among the second trenches 22 to the third trench 23 provided in the termination region 103 is electrically connected to the second gate electrode pad 105. A part of the second trench 22x may be in contact with the guard ring region 34.

A part of the second conductive layer 52 is electrically connected to the upper electrode 12. In FIG. 4, the second conductive layer 52 in contact with the upper electrode 12 is electrically connected to the upper electrode 12.

Hereinafter, the second trench 22 in which the second conductive layer 52 electrically connected to the second gate electrode pad 105 is provided is referred to as a second gate trench. In addition, the second trench 22 in which the second conductive layer 52 electrically connected to the upper electrode 12 is provided is referred to as a second dummy trench.

The first diode region 102a includes the plurality of second trenches 22. The first diode region 102a includes the second trench 22x closest to the third trench 23 provided in the termination region 103 in the second direction. The second trench 22x is a second gate trench. In FIG. 4, all the second trenches 22 included in the first diode region 102a are second gate trenches.

The second diode region 102b includes the plurality of second trenches 22. In FIG. 4, all the second trenches 22 included in the second diode region 102b are second dummy trenches.

A ratio of a number of the second trenches 22 in which the second conductive layer 52 electrically connected to the second gate electrode pad 105 is provided among the second trenches 22 in the first diode region 102a to a number of the second trenches 22 included in the first diode region 102a is larger than a ratio of a number of the second trenches 22 in which the second conductive layer 52 electrically connected to the second gate electrode pad 105 is provided among the second trenches 22 in the second diode region 102b to a number of the second trenches 22 included in the second diode region 102b.

In other words, the ratio of the number of the second gate trenches in the first diode region 102a to the number of second trenches 22 is larger than the ratio of the number of the second gate trenches in the second diode region 102b to the number of the second trenches 22 included in the second diode region 102b.

For example, in the case of FIG. 4, the number of the second trenches 22 in the first diode region 102a is 5, and the number of the second gate trenches is 5. Therefore, the ratio of the number of the second gate trenches to the number of the second trenches 22 in the first diode region 102a is 100%. In addition, the number of the second trenches 22 in the second diode region 102b is 3, and the number of the second gate trenches is 0. Therefore, the ratio of the number of the second gate trenches to the number of the second trenches 22 in the second diode region 102b is 0%.

For example, in a case of comparing the ratio of the number of the second gate trenches in the first diode region 102a to the number of the second trenches 22 and the ratio of the number of the second gate trenches in the second diode region 102b to the number of the second trenches 22, 5 second gate trenches continuous in the second direction are extracted from each region, and the ratios are compared.

A distance (d in FIG. 4) between the second trench 22y most distant from the guard ring region 34 in the second direction among the second trenches 22 having the second conductive layer 52 electrically connected to the second gate electrode pad 105 and the guard ring region 34 is equal to or more than a thickness (t in FIG. 4) in the direction from the first face F1 to the second face F2 of the semiconductor layer 10.

The second insulating film 42 is provided between the second conductive layer 52 and the semiconductor layer 10. The second insulating film 42 is provided between the second conductive layer 52 and the drift region 27, and between the second conductive layer 52 and the anode region 32. The second insulating film 42 is in contact with the drift region 27 and the anode region 32. The second insulating film 42 is, for example, silicon oxide.

The interlayer insulating layer 61 is provided between the second conductive layer 52 and the upper electrode 12, and between the semiconductor layer 10 and the upper electrode 12. For example, the second conductive layer 52 and the upper electrode 12 are electrically connected using an opening provided in the interlayer insulating layer 61.

The termination region 103 includes the semiconductor layer 10, the upper electrode 12 (first electrode), the lower electrode 14 (second electrode), the third insulating film 43, the third conductive layer 53, and the interlayer insulating layer 61.

In the semiconductor layer 10 of the termination region 103, the third trench 23, the terminal cathode region 35 (eighth semiconductor region), the drift region 27 (second semiconductor region), the guard ring region 34 (seventh semiconductor region), and the guard ring contact region 36 are provided.

In the termination region 103, a parasitic diode is formed between the upper electrode 12 and the lower electrode 14.

The upper electrode 12 functions as an anode electrode of the parasitic diode in the termination region 103. The upper electrode 12 is in contact with the guard ring contact region 36. The upper electrode 12 is electrically connected to the guard ring contact region 36. The upper electrode 12 is electrically connected to the guard ring region 34 via the guard ring contact region 36. The upper electrode 12 may be in direct contact with the guard ring region 34. In this case, for example, the upper electrode 12 and the guard ring region 34 have a Schottky junction.

The lower electrode 14 functions as a cathode electrode of the parasitic diode in the termination region 103. The lower electrode 14 is in contact with the terminal cathode region 35.

The terminal cathode region 35 is an n⁺ type semiconductor region. The terminal cathode region 35 is in contact with the second face F2. The terminal cathode region 35 serves as a supply source of electrons in a case where the parasitic diode is in the ON state. The terminal cathode region 35 is in contact with the lower electrode 14.

The drift region 27 is an n⁻ type semiconductor region. The drift region 27 is provided between the terminal cathode region 35 and the first face F1. The n type impurity concentration of the drift region 27 is lower than the n type impurity concentration of the terminal cathode region 35.

The drift region 27 serves as a path of an ON current in a case where the parasitic diode is in the ON state.

The guard ring region 34 is a p type semiconductor region. The guard ring region 34 is provided between the drift region 27 and the first face F1. The guard ring region 34 sandwiches the drift region 27 with the terminal cathode region 35.

A depth of the guard ring region 34 is deeper than the depth of the anode region 32. The depth of the guard ring region 34 is deeper than a depth of the third trench 23. The depth of the guard ring region 34 is deeper than the depth of the second trench 22.

The guard ring region 34 surrounds the transistor region 101 and the diode region 102. The guard ring region 34 is annularly provided on the first face F1. The guard ring region 34 has a function of relaxing an intensity of an electric field applied to a termination portion of a pn junction in the transistor region 101 and the diode region 102.

The guard ring region 34 serves as a supply source of holes in a case where the parasitic diode is in the ON state.

For example, an annular p type region may be provided as a guard ring outside the guard ring region 34 of the termination region 103 so as to surround the guard ring region 34.

The p type impurity concentration of the guard ring region 34 is higher than the p type impurity concentration of the anode region 32, for example. The p type impurity concentration of the guard ring region 34 is, for example, equal to or more than 5 times and equal to or less than 50 times of the p type impurity concentration of the anode region 32.

The guard ring contact region 36 is a p⁺ type semiconductor region. The guard ring contact region 36 is provided between the guard ring region 34 and the first face F1.

The guard ring contact region 36 is in contact with the upper electrode 12. The guard ring contact region 36 is electrically connected to the upper electrode 12.

A p type impurity concentration of the guard ring contact region 36 is higher than the p type impurity concentration of the guard ring region 34.

The third trench 23 is provided in contact with the guard ring region 34 on a side of the first face F1 of the semiconductor layer 10. The third trench 23 is a groove provided in the semiconductor layer 10. The third trench 23 is a part of the semiconductor layer 10.

As illustrated in FIG. 5, the third trench 23 extends in the first direction parallel to the first face F1 in the first face F1. For example, a plurality of the third trenches 23 is provided.

The third trench 23 has, for example, a stripe shape. The plurality of third trenches 23 are disposed repeatedly in the second direction perpendicular to the first direction.

The third trench 23 is provided between the guard ring region 34 and the first face F1. The depth of the third trench 23 is shallower than the depth of the guard ring region 34. The third trench 23 is separated from the drift region 27 with the guard ring region 34 interposed therebetween. The third trench 23 is in contact with the guard ring region 34. The depth of the third trench 23 is, for example, equal to or less than 8 μm.

The third conductive layer 53 is provided in the third trench 23. The third conductive layer 53 is, for example, a semiconductor or a metal. The third conductive layer 53 is amorphous silicon or polycrystalline silicon, for example, containing n type impurities or p type impurities.

The third conductive layer 53 is electrically connected to the upper electrode 12. The third conductive layer 53 is in contact with the upper electrode 12.

The interlayer insulating layer 61 is provided between the third conductive layer 53 and the upper electrode 12, and between the semiconductor layer 10 and the upper electrode 12. For example, the third conductive layer 53 and the upper electrode 12 are electrically connected using an opening provided in the interlayer insulating layer 61.

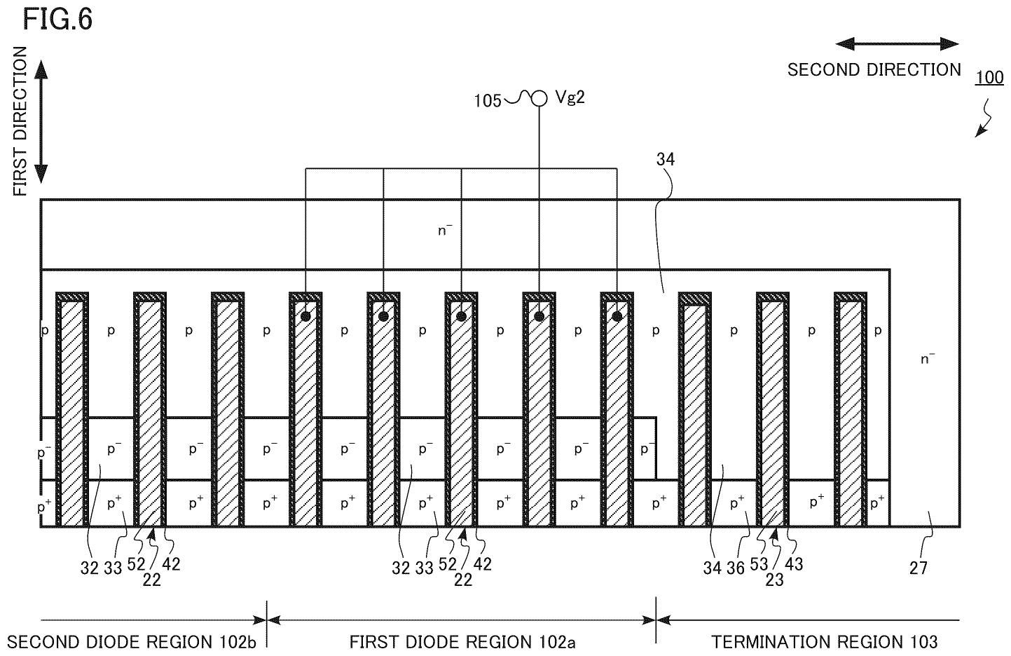

FIG. 6 is a schematic top view of a part of the semiconductor device according to the first embodiment. FIG. 6 is a top view of the first face F1. FIG. 6 is a top view of a region R surrounded by a dotted line in FIG. 1.

As illustrated in FIG. 6, in the first face F1, an end portion of the second trench 22 in the first direction is in contact with the guard ring region 34.

Next, a method of driving the RC-IGBT 100 will be described.

In the OFF state of the IGBT in the transistor region 101, for example, an emitter voltage is applied to the upper electrode 12. The emitter voltage is, for example, 0 V. A collector voltage is applied to the lower electrode 14. The collector voltage is, for example, equal to or more than 200 V and equal to or less than 6500 V.

In the OFF state of the IGBT, a turn-off voltage is applied to the first gate electrode pad 104. In the OFF state of the IGBT, a turn-off voltage is applied to the first conductive layer 51 in the first gate trench of the transistor region 101. The turn-off voltage is a voltage less than a threshold voltage at which the transistor having the first gate trench is not turned on, and is, for example, 0 V or a negative voltage.

In a case where the IGBT is turned on, the first gate voltage (Vg1) is applied to the first gate electrode pad 104. The first gate voltage (Vg1) is a so-called turn-on voltage. When the IGBT is turned on, a first gate voltage (Vg1) is applied to the first conductive layer 51 in the first gate trench of the transistor region 101.

The first gate voltage (Vg1) is a positive voltage that exceeds the threshold voltage of the transistor having the first gate trench. The first gate voltage (Vg1) is, for example, 15 V. By the application of the first gate voltage (Vg1) to the first conductive layer 51, an n type inversion layer is formed in the cell base region 28 in contact with the first gate trench, and the transistor having the first gate trench is turned on.

In a case where a freewheeling current is caused to flow using the diode of the diode region 102 while the IGBT of the transistor region 101 is in the OFF state, the second gate voltage (Vg2) is applied to the second gate electrode pad 105. For example, the second gate voltage (Vg2) is applied to the second gate electrode pad 105 at the time of conduction of the diode and at the time of reverse recovery.

In a case where a freewheeling current is caused to flow using a diode, the second gate voltage (Vg2) is applied to the second conductive layer 52 in the second gate trench of the diode region 102.

The second gate voltage (Vg2) is a negative voltage. The second gate voltage (Vg2) is, for example, −15 V.

The application of the negative second gate voltage (Vg2) to the second conductive layer 52 forms a p type accumulation layer in the anode region 32 in contact with the second gate trench. In addition, by applying the second gate voltage (Vg2) to the second conductive layer 52, a p type inversion layer is formed in the drift region 27 in contact with the second gate trench.

Next, functions and effects of the semiconductor device according to the first embodiment will be described.

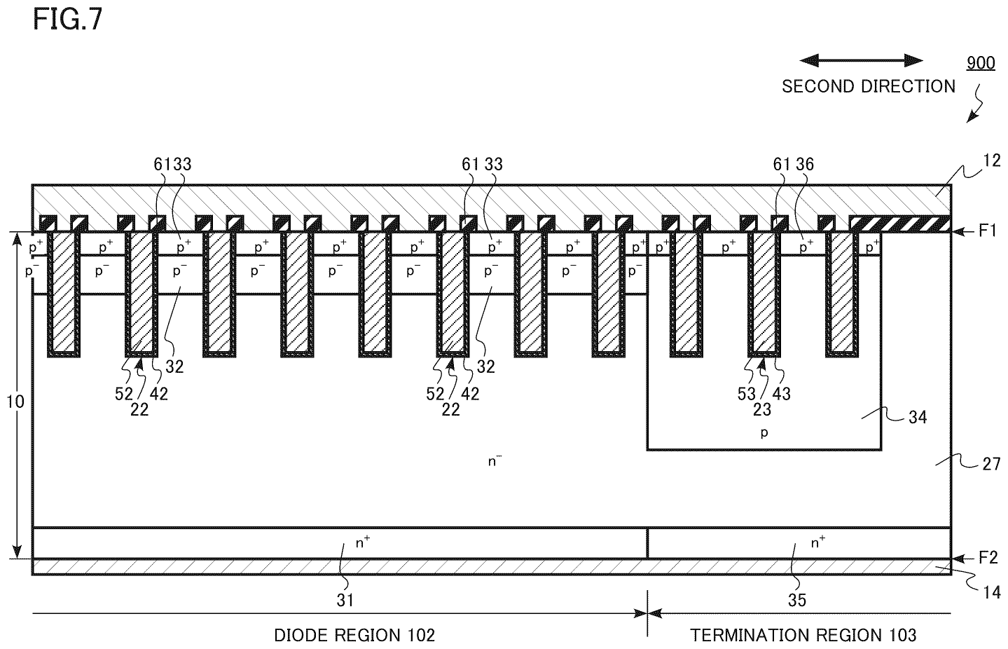

FIG. 7 is a schematic cross-sectional view of a part of a semiconductor device according to a comparative example. FIG. 7 is a diagram corresponding to FIG. 4 of the first embodiment.

The semiconductor device of the comparative example is an RC-IGBT 900 in which an IGBT and a freewheeling diode are formed on the same semiconductor chip. The RC-IGBT 900 of the comparative example is different from the RC-IGBT 100 of the first embodiment in that the second conductive layer 52 in all the second trenches 22 provided in the diode region 102 is electrically connected to the upper electrode 12. In other words, the RC-IGBT 900 of the comparative example is different from the RC-IGBT 100 of the first embodiment in that all the second trenches 22 provided in the diode region 102 are the second dummy trenches.

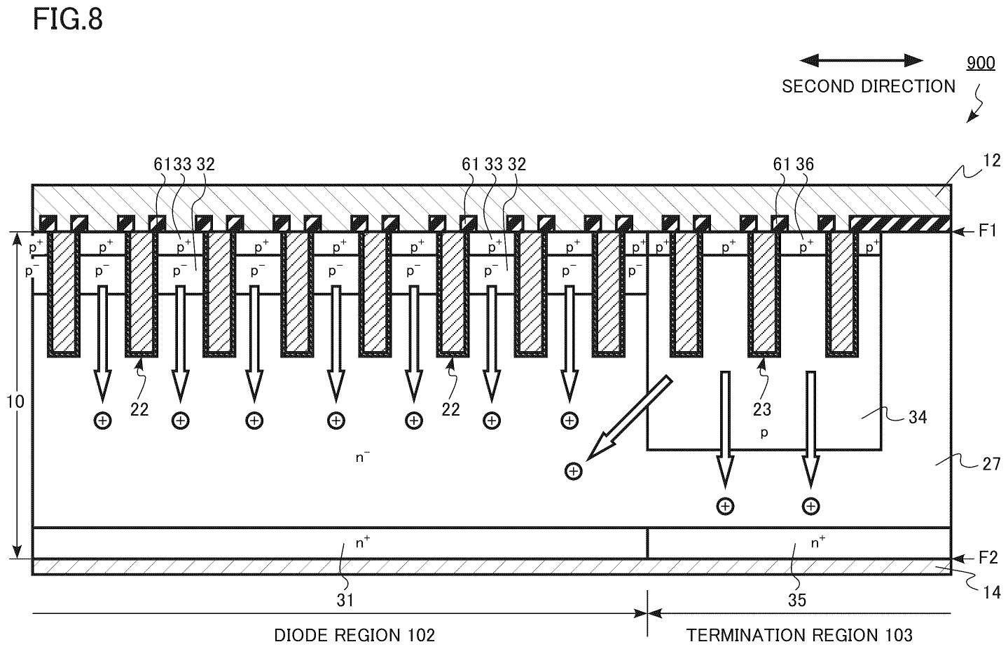

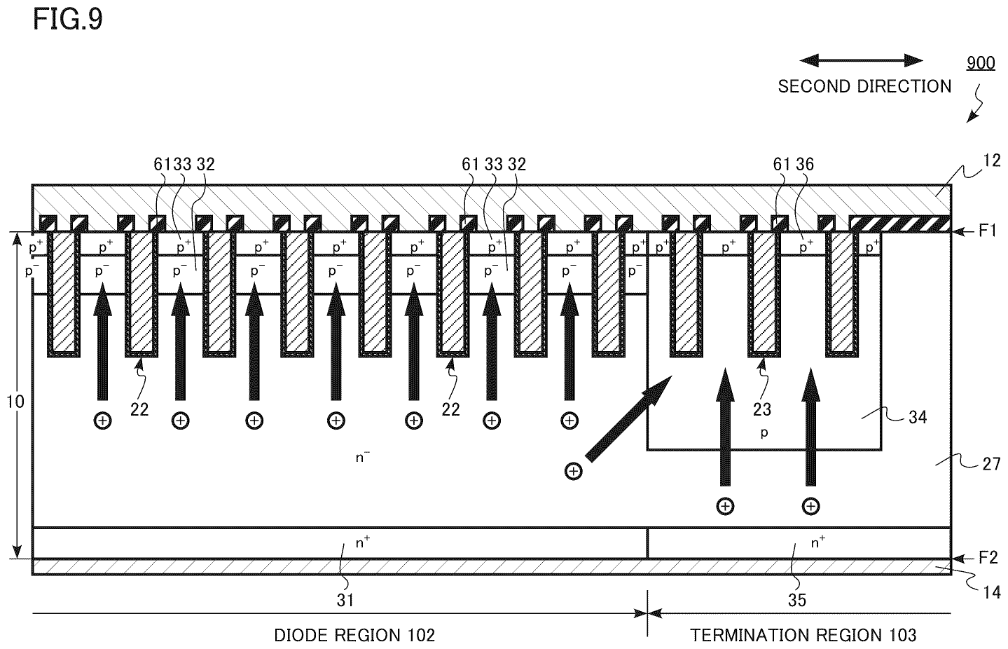

FIGS. 8 and 9 are explanatory diagrams of a problem of the semiconductor device according to the comparative example. FIG. 8 is a diagram illustrating a flow of a hole current in a case in which the diode of the diode region 102 is in a conducting state. FIG. 9 is a diagram illustrating the flow of the hole current in a case in which the diode of the diode region 102 is in the reverse recovery state. FIGS. 8 and 9 are diagrams corresponding to FIG. 7.

As illustrated in FIG. 8, in a case where the diode of the diode region 102 is in a conducting state, holes are injected from the anode region 32 into the drift region 27. The parasitic diode in the termination region 103 is also brought into a conducting state, and holes are injected from the guard ring region 34 into the drift region 27. Therefore, in the drift region 27 in the vicinity of an end portion of the diode region 102 on a side of the termination region 103, holes are excessive.

As illustrated in FIG. 9, in a case where the diode of the diode region 102 is in the reverse recovery state, holes are discharged from the drift region 27 to the upper electrode 12 through the anode region 32. Holes are discharged from drift region 27 to upper electrode 12 through guard ring region 34.

In the drift region 27 in the vicinity of the end portion of the diode region 102 on the termination region 103 side, since holes are in an excessive state, discharge of holes to the upper electrode 12 is delayed. Therefore, the reverse recovery current (Irr) at the time of reverse recovery of the diode increases, and the reverse recovery loss (Err) of the diode increases.

For example, when the RC-IGBT 900 is used as a switching element of an inverter circuit, two RC-IGBTs 900 are provided in series on a high side and a low side, respectively. For example, when the reverse recovery loss (Err) of the diode of one RC-IGBT 900 increases, the turn-on loss (Eon) of the IGBT of the other RC-IGBT 900 increases, and the loss of the inverter circuit increases. Therefore, it is desired to reduce the reverse recovery loss (Err) of the diode of the RC-IGBT 900.

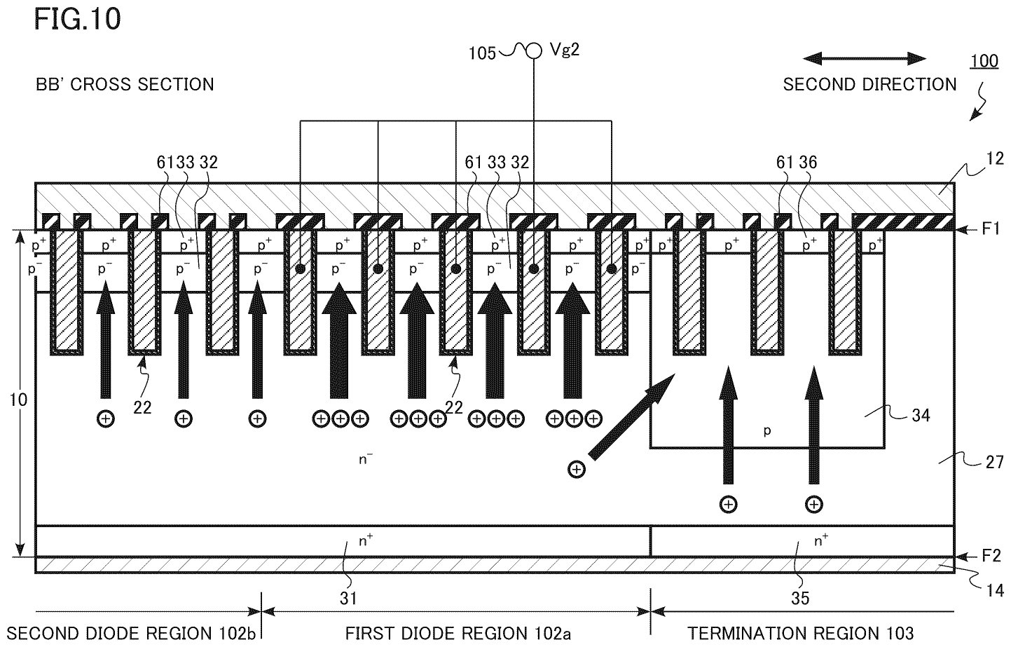

FIG. 10 is an explanatory diagram of functions and effects of the semiconductor device of the first embodiment. FIG. 10 is a diagram illustrating the flow of the hole current in a case in which the diode in the diode region 102 is of the reverse recovery state. FIG. 10 is a diagram corresponding to FIG. 4.

In the RC-IGBT 100 of the first embodiment, the second conductive layer 52 in the second trench 22 in the vicinity of the end portion of the diode region 102 on a side of the termination region 103 is electrically connected to the second gate electrode pad 105. In other words, the second trench 22 near the end portion of the diode region 102 on a side of the termination region 103 is a second gate trench.

For example, in a case where the diode of the diode region 102 is in the reverse recovery state, the second gate voltage (Vg2) is applied to the second conductive layer 52 in the second gate trench. The second gate voltage (Vg2) is a negative voltage.

The application of the negative second gate voltage (Vg2) to the second conductive layer 52 forms a p type accumulation layer in the anode region 32 in contact with the second gate trench. Therefore, an electric resistance of the anode region 32 in contact with the second gate trench is reduced.

In addition, by applying the second gate voltage (Vg2) to the second conductive layer 52, a p type inversion layer in which holes are induced is formed in the drift region 27 in contact with the second gate trench. Therefore, the electric resistance of the drift region 27 in contact with the second gate trench is reduced.

Therefore, as illustrated in FIG. 10, the discharge of holes from the drift region 27 to the upper electrode 12 is promoted in the vicinity of the end portion of the diode region 102 on a side of the termination region 103. Therefore, the reverse recovery current (Irr) at the time of reverse recovery of the diode decreases, and the reverse recovery loss (Err) of the diode decreases.

By reducing the reverse recovery loss (Err) of the diode, the turn-on loss (Eon) in a case where the RC-IGBT 100 is used as a switching element of the inverter circuit is also reduced. Therefore, the loss of the inverter circuit using the RC-IGBT 100 is reduced.

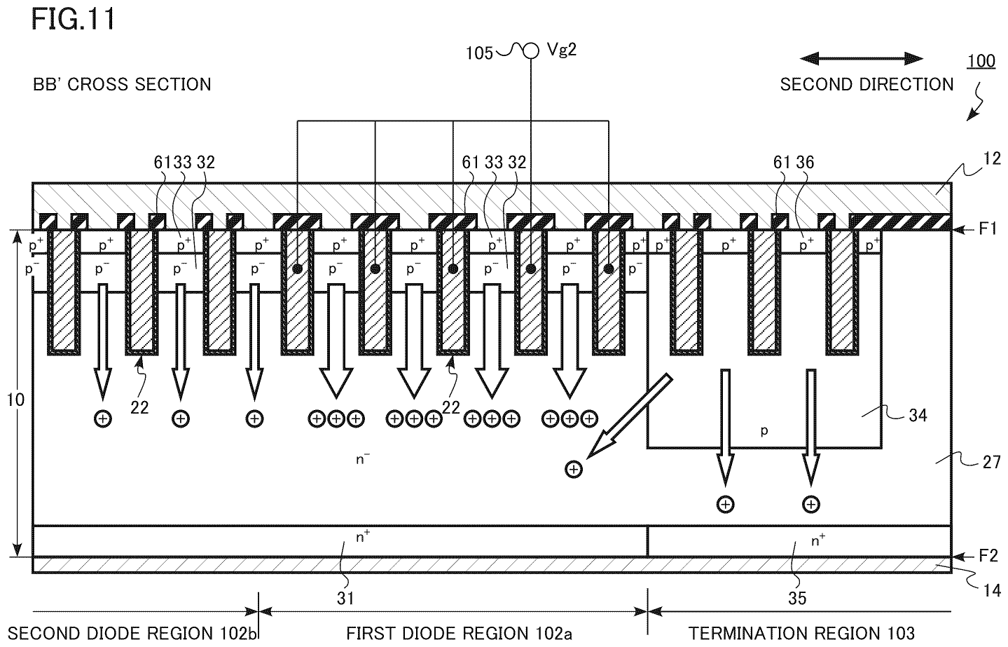

FIG. 11 is an explanatory diagram of functions and effects of the semiconductor device of the first embodiment. FIG. 11 is a diagram illustrating a flow of a hole current in a case in which the diode of the diode region 102 is in a conducting state. FIG. 11 is a diagram corresponding to FIG. 4.

For example, in a case where the diode of the diode region 102 is in a conducting state, the second gate voltage (Vg2) is applied to the second conductive layer 52 in the second gate trench. The second gate voltage (Vg2) is a negative voltage.

The application of the negative second gate voltage (Vg2) to the second conductive layer 52 forms a p type accumulation layer in the anode region 32 in contact with the second gate trench. Therefore, the hole density of the anode region 32 in contact with the second gate trench increases.

In addition, by applying the second gate voltage (Vg2) to the second conductive layer 52, a p type inversion layer is formed in the drift region 27 in contact with the second gate trench. Therefore, the hole density of the drift region 27 in contact with the second gate trench increases.

Therefore, as shown in FIG. 11, injection of holes from the anode region 32 into the drift region 27 is promoted. Therefore, a forward voltage (VE) at the time of conduction of the diode decreases. Therefore, the conduction loss of the diode is reduced.

According to the first embodiment, the reverse recovery loss (Err), the turn-on loss (Eon), and the conduction loss of the RC-IGBT 100 are reduced.

In the RC-IGBT 100, from the viewpoint of reducing the charge/discharge loss caused by the second gate voltage (Vg2) applied to the second gate electrode pad 105, it is preferable to provide the second diode region 102b in which the ratio of the second gate trench is low with respect to the first diode region 102a. As the number of second gate trenches decreases, power consumed for charging and discharging of the second conductive layer 52 can be reduced.

It is preferable that the distance (d in FIG. 4) between the second trench 22y most distant from the guard ring region 34 in the second direction among the second trenches 22 having the second conductive layer 52 electrically connected to the second gate electrode pad 105 and the guard ring region 34 is equal to or more than the thickness (t in FIG. 4) in the direction from the first face F1 to the second face F2 of the semiconductor layer 10. A diffusion distance of the holes injected from the guard ring region 34 in the second direction is about the thickness t of the semiconductor layer 10, and by satisfying the above condition, the reverse recovery loss of the diode can be effectively suppressed.

As illustrated in FIG. 6, in the first face F1, the end portion of the second trench 22 in the first direction is preferably in contact with the guard ring region 34. According to the above aspect, the discharge of holes from the drift region 27 to the upper electrode 12 is promoted not only in the vicinity of the end of the diode region 102 in the second direction but also in the vicinity of the end of the diode region 102 in the first direction, and the reverse recovery loss (Err) of the diode can be reduced.

### First Modified Example

A semiconductor device according to a first modified example of the first embodiment is different from the semiconductor device according to the first embodiment in that the second conductive layers provided in a part of the second trenches in the first region of the diode region are electrically connected to the first electrode.

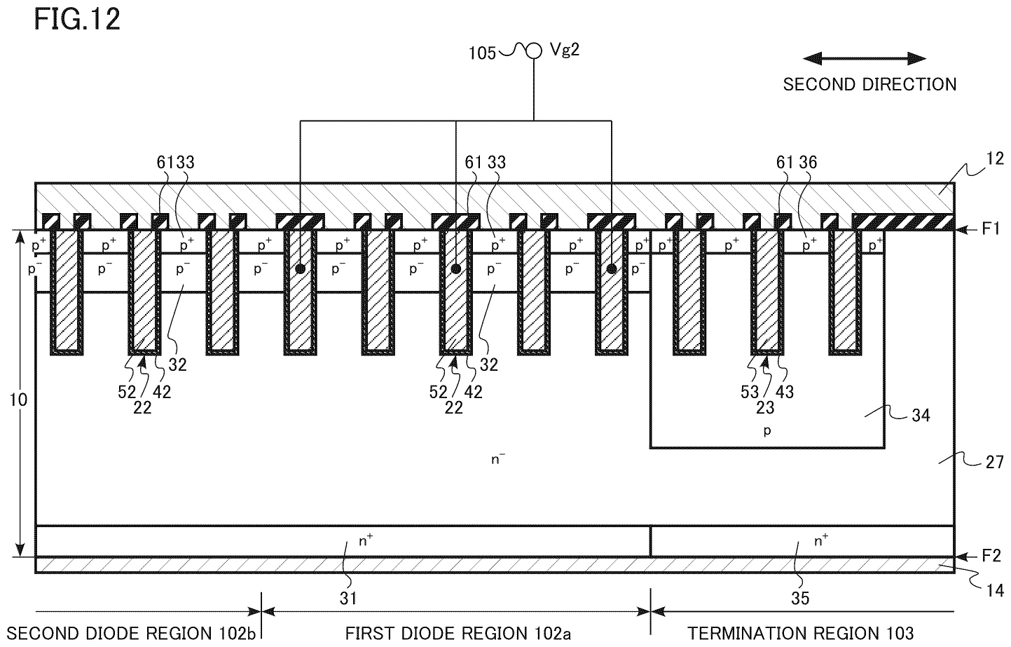

FIG. 12 is a schematic cross-sectional view of a part of a semiconductor device according to the first modified example of the first embodiment. FIG. 12 is a diagram corresponding to FIG. 4 of the first embodiment.

As illustrated in FIG. 12, the second conductive layer 52 in the second trench 22 as a part of the second trenches 22 in the first diode region 102a is electrically connected to the upper electrode 12. In other words, the part of the second trench 22 in the first diode region 102a is a second dummy gate trench.

In the case of FIG. 12, the number of the second trenches 22 in the first diode region 102a is 5, and the number of the second gate trenches is 3. Therefore, the ratio of the number of the second gate trenches to the number of the second trenches 22 in the first diode region 102a is 60%. In addition, the number of the second trenches 22 in the second diode region 102b is 3, and the number of the second gate trenches is 0. Therefore, the ratio of the number of the second gate trenches to the number of the second trenches 22 in the second diode region 102b is 0%.

For example, the second conductive layer 52 in the second trench 22 as a part of the second trenches 22 in the second diode region 102b may be electrically connected to the second gate electrode pad 105. For example, in FIG. 12, in a case where one second gate trench is provided in the second diode region 102b, the ratio of the number of the second gate trenches to the number of the second trenches 22 in the second diode region 102b is 33.3%.

In the case of FIG. 12, an arrangement pattern of the second gate trench and the second dummy trench in the second direction in the first diode region 102a is the same as an arrangement pattern of the first gate trench and the first dummy trench in the second direction in the transistor region 101 illustrated in the diagram of the first embodiment. By making the arrangement pattern of the second gate trench and the second dummy trench in the second direction in the first diode region 102a and the arrangement pattern of the first gate trench and the first dummy trench in the second direction in the transistor region 101 the same, for example, designing of a pattern of the RC-IGBT becomes easy.

According to the first modified example of the first embodiment, similarly to the first embodiment, the reverse recovery loss (Err), the turn-on loss (Eon), and the conduction loss of the RC-IGBT are reduced.

### Second Modified Example

A semiconductor device according to a second modified example of the first embodiment is different from the semiconductor device according to the first embodiment in that a second conductive layers provided in all the second trenches is electrically connected to a second electrode pad.

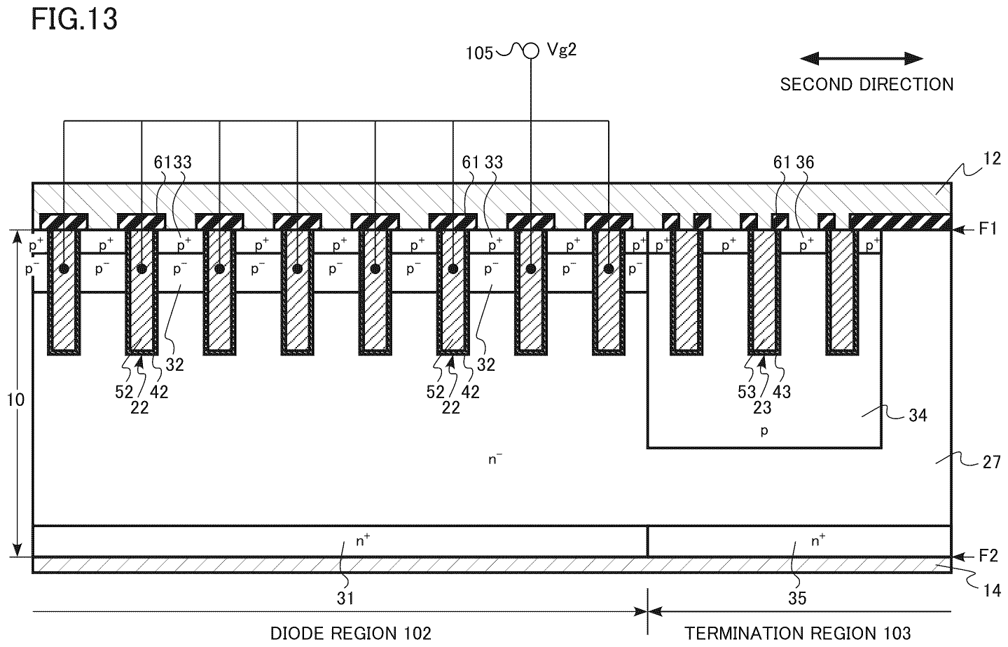

FIG. 13 is a schematic cross-sectional view of a part of a semiconductor device according to the second modified example of the first embodiment. FIG. 13 is a diagram corresponding to FIG. 4 of the first embodiment.

As illustrated in FIG. 13, the second conductive layer 52 provided in all the second trenches 22 is electrically connected to the second gate electrode pad 105.

According to the second modified example of the first embodiment, similarly to the first embodiment, the reverse recovery loss (Err), the turn-on loss (Eon), and the conduction loss of the RC-IGBT are reduced. In addition, as the second gate trench in the diode region 102 increases, the forward voltage (Vr) at the time of conduction of the diode further decreases, and the conduction loss of the diode decreases.

### Third Modified Example

A semiconductor device according to a third modified example of the first embodiment is different from the semiconductor device according to the first embodiment in that the termination region further includes: a ninth semiconductor region of a first conductivity type, the ninth semiconductor region being provided in the semiconductor layer, the ninth semiconductor region being provided between the second semiconductor region and the second face, the ninth semiconductor region having a first conductivity type impurity concentration higher than a first conductivity type impurity concentration of the seventh semiconductor region, and the second electrode is in contact with the ninth semiconductor region.

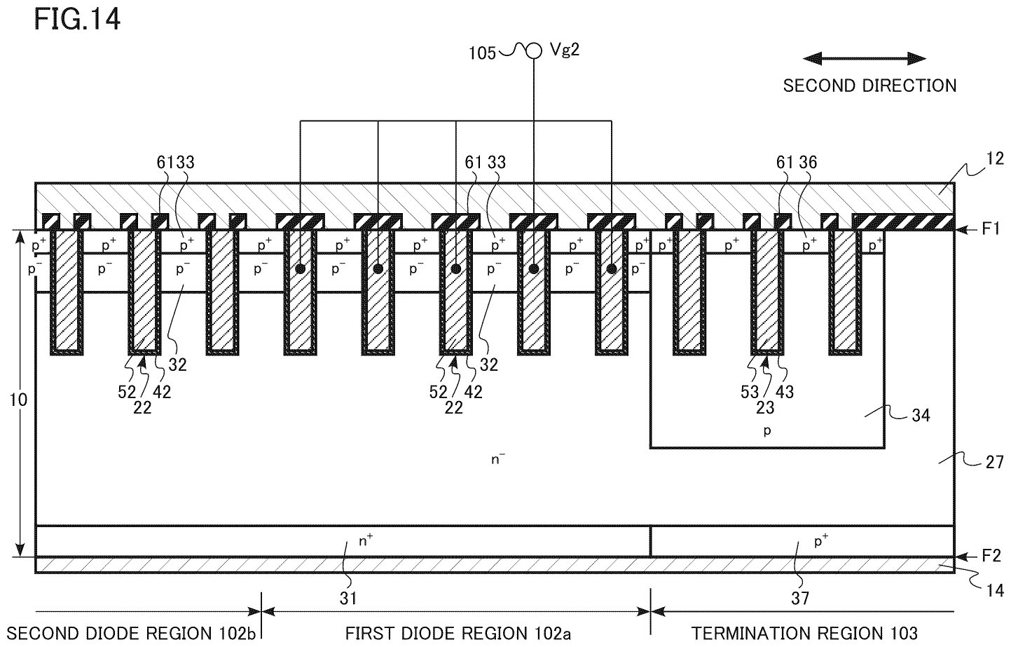

FIG. 14 is a schematic cross-sectional view of a part of the semiconductor device according to the third modified example of the first embodiment. FIG. 14 is a diagram corresponding to FIG. 4 of the first embodiment.

As illustrated in FIG. 14, the termination region 103 includes a p⁺ type termination back surface p region 37 between the drift region 27 and the second face F2, and the termination back surface p region 37 is in contact with the lower electrode 14.

A p type impurity concentration of the termination back surface p region 37 is higher than the p type impurity concentration of the guard ring region 34.

According to the third modified example of the first embodiment, similarly to the first embodiment, the reverse recovery loss (Err), the turn-on loss (Eon), and the conduction loss of the RC-IGBT are reduced. In addition, since the termination region 103 includes the termination back surface p region 37, hole injection from the parasitic diode of the termination region 103 is suppressed. Therefore, the reverse recovery loss (Err) and the turn-on loss (Eon) are further reduced.

As described above, according to the first embodiment and the modified examples, it is possible to realize a semiconductor device including an RC-IGBT having an IGBT and a diode and capable of reducing a loss.

### Second Embodiment

A semiconductor device of a second embodiment is different from the semiconductor device according to the first embodiment in that a third conductive layer provided in the third trench is electrically connected to a second electrode pad. Hereinafter, descriptions of contents overlapping with the first embodiment may be partially omitted.

The semiconductor device of the second embodiment is an RC-IGBT 200 in which an IGBT and a freewheeling diode are formed on the same semiconductor chip.

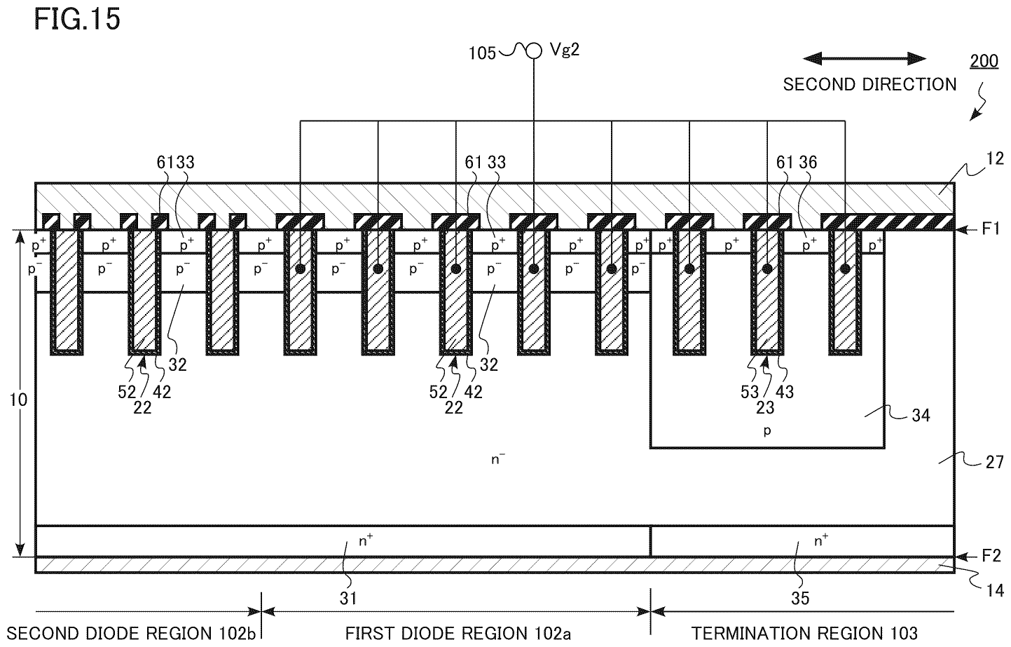

FIG. 15 is a schematic cross-sectional view of a part of the semiconductor device according to the second embodiment. FIG. 15 is a diagram corresponding to FIG. 4 of the first embodiment.

A plurality of third trenches 23 are provided in the semiconductor layer 10 in the termination region 103 of the RC-IGBT 200. As illustrated in FIG. 15, the third conductive layer 53 provided in all the third trenches 23 is electrically connected to the second gate electrode pad 105.

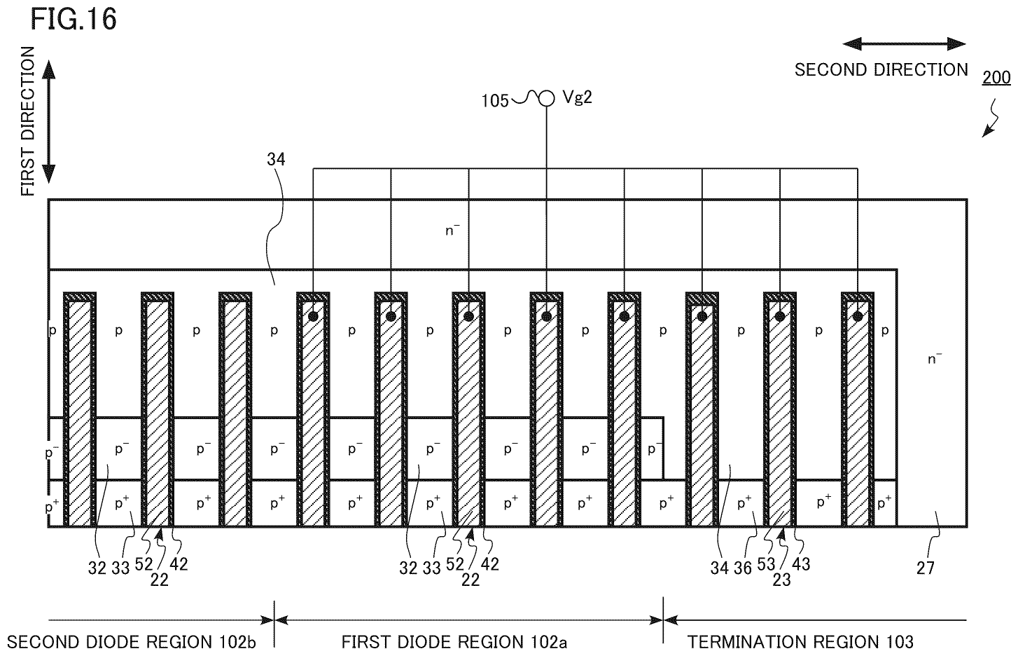

FIG. 16 is a schematic top view of a part of the semiconductor device according to the second embodiment. FIG. 16 is a top view of the first face F1. FIG. 16 is a diagram corresponding to FIG. 6 of the first embodiment.

As illustrated in FIG. 16, in the first face F1, the end portion of the second trench 22 in the first direction is in contact with the guard ring region 34.

In the RC-IGBT 200 of the second embodiment, similarly to the RC-IGBT 100 of the first embodiment, the second conductive layer 52 in the second trench 22 in the vicinity of the end portion of the diode region 102 on a side of the termination region 103 is electrically connected to the second gate electrode pad 105. Therefore, similarly to the RC-IGBT 100, in the RC-IGBT 200, the reverse recovery loss (Err), the turn-on loss (Eon), and the conduction loss are reduced.

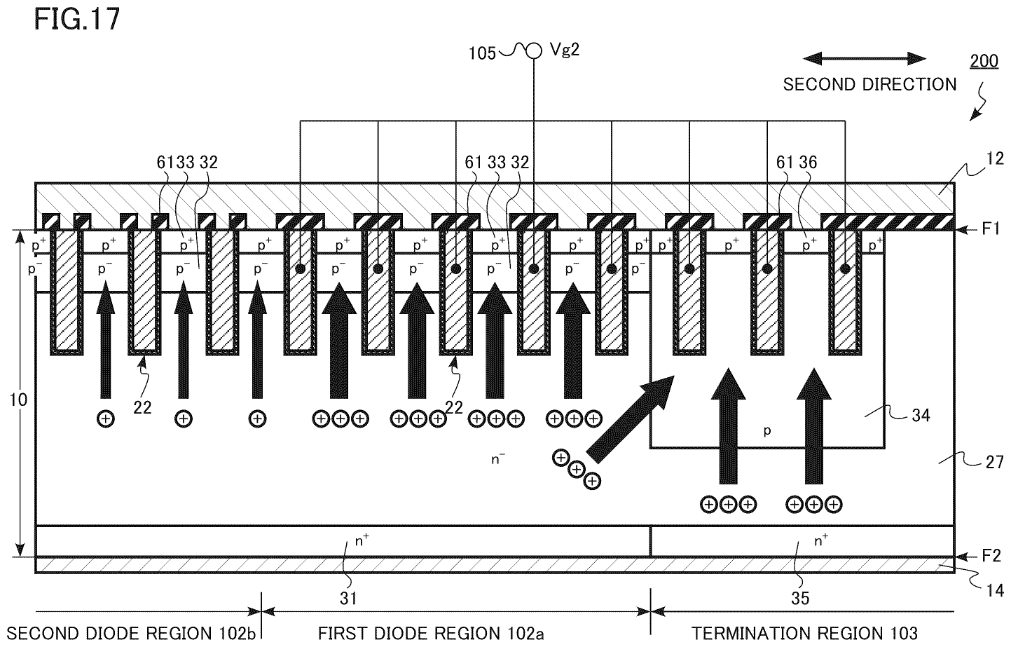

FIG. 17 is an explanatory diagram of functions and effects of the semiconductor device of the second embodiment. FIG. 17 is a diagram illustrating the flow of the hole current in a case in which the diode in the diode region 102 is of the reverse recovery state. FIG. 17 is a diagram corresponding to FIG. 15.

In the RC-IGBT 200 of the second embodiment, the third conductive layer 53 in the third trench 23 of the termination region 103 is electrically connected to the second gate electrode pad 105.

For example, in a case where the diode of the diode region 102 is in the reverse recovery state, the second gate voltage (Vg2) is applied to the third conductive layer 53 in the third gate trench. The second gate voltage (Vg2) is a negative voltage.

The application of the negative second gate voltage (Vg2) to the third conductive layer 53 forms a p type accumulation layer in the guard ring region 34 in contact with the third trench 23. Therefore, the electric resistance of the guard ring region 34 in contact with the third trench is reduced.

Therefore, as shown in FIG. 17, discharge of holes from the drift region 27 to the upper electrode 12 via the guard ring region 34 is promoted. Therefore, the reverse recovery current (Irr) at the time of reverse recovery of the diode further decreases, and the reverse recovery loss (Err) of the diode further decreases.

By reducing the reverse recovery loss (Err) of the diode, the turn-on loss (Eon) in a case where the RC-IGBT 200 is used as a switching element of the inverter circuit is also further reduced.

The end of the second trench 22 in the first direction is in contact with the guard ring region 34. Therefore, in a case where the diode is in the reverse recovery state, a p type accumulation layer is formed in the guard ring region 34 in contact with the second gate trench at the end in the first direction existing in the guard ring region 34. Therefore, discharge of holes from the drift region 27 to the upper electrode 12 via the guard ring region 34 is further promoted.

In particular, at a corner portion of the diode region 102 as illustrated in FIG. 16, the guard ring region 34 of the termination region 103 is provided both in the first direction and the second direction. Therefore, injection of holes into the drift region 27 at the time of conduction of the diode is concentrated, and the density of holes in the drift region 27 becomes particularly high. Therefore, in particular, an effect of discharge of holes by the end portion of the second trench 22 in the first direction being in contact with the guard ring region 34 particularly noticeable.

The p type impurity concentration of the guard ring region 34 is preferably higher than the p type impurity concentration of the anode region 32. Since the p type impurity concentration of the guard ring region 34 is high, discharge of holes via the guard ring region 34 is further promoted, and the reverse recovery loss (Err) of the diode is further reduced.

Note that only the third conductive layer 53 provided in a part of the third trenches 23 may be electrically connected to the second gate electrode pad 105.

The number of the third trenches may be one.

### First Modified Example

A semiconductor device according to a first modified example of the second embodiment is different from the semiconductor device according to the second embodiment in that the second conductive layers provided in a part of the second trenches in the first region of the diode region are electrically connected to the first electrode.

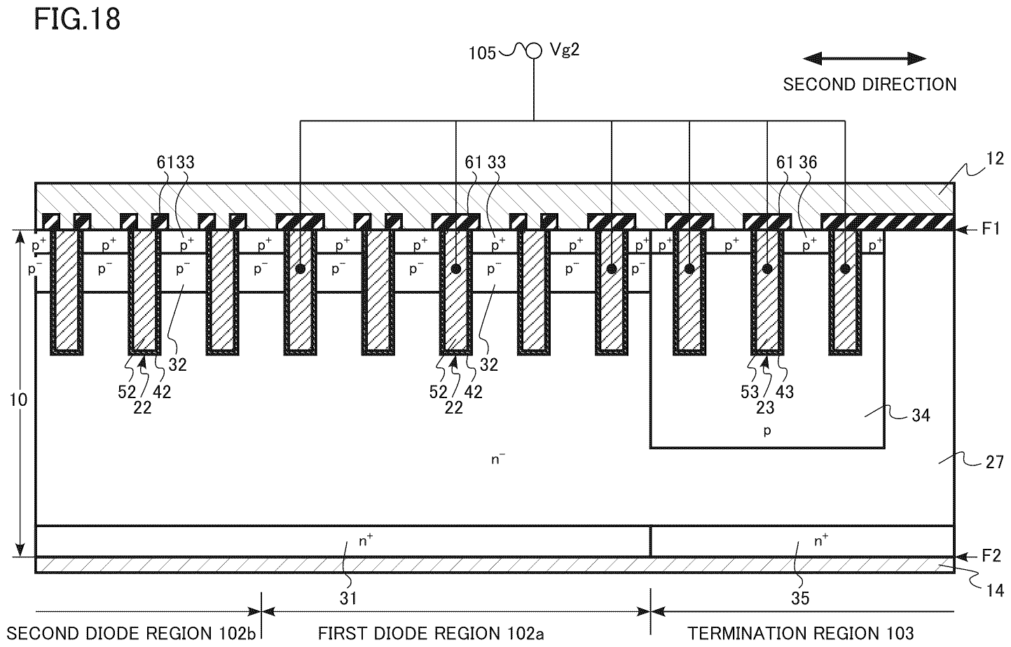

FIG. 18 is a schematic cross-sectional view of a part of a semiconductor device according to the first modified example of the second embodiment. FIG. 18 is a diagram corresponding to FIG. 15 of the second embodiment.

As illustrated in FIG. 18, the second conductive layer 52 in the second trench 22 as a part of the second trenches 22 in the first diode region 102a is electrically connected to the upper electrode 12. In other words, the part of the second trench 22 in the first diode region 102a is a second dummy gate trench.

According to the first modified example of the second embodiment, similarly to the second embodiment, the reverse recovery loss (Err), the turn-on loss (Eon), and the conduction loss of the RC-IGBT are reduced.

### Second Modified Example

A semiconductor device according to a second modified example of the second embodiment is different from the semiconductor device according to the second embodiment in that a second conductive layers provided in all the second trenches is electrically connected to a second electrode pad.

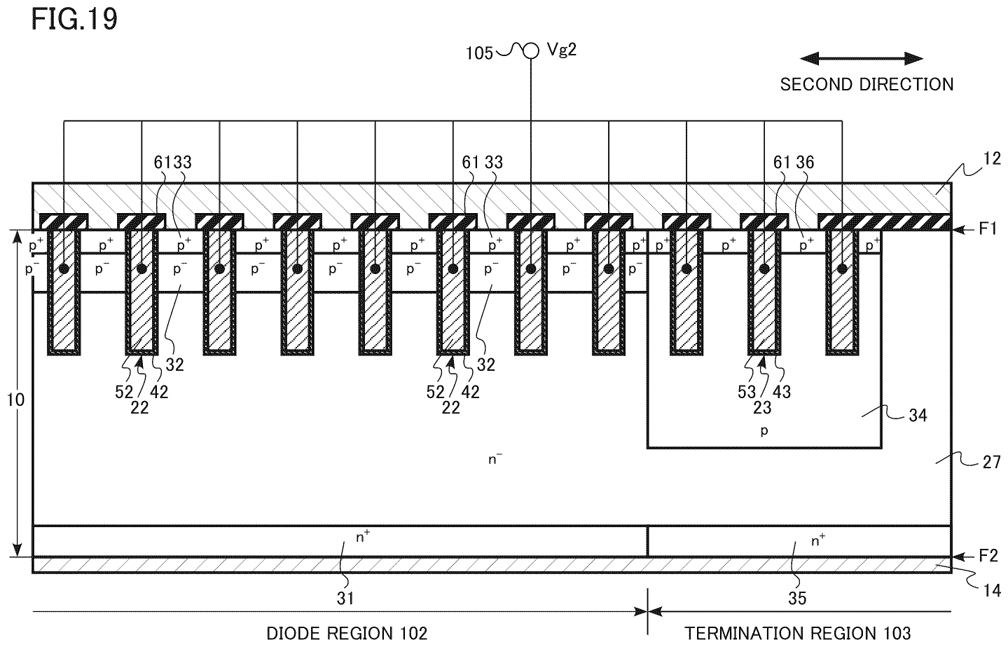

FIG. 19 is a schematic cross-sectional view of a part of a semiconductor device according to the second modified example of the second embodiment. FIG. 19 is a diagram corresponding to FIG. 15 of the second embodiment.

As illustrated in FIG. 19, the second conductive layer 52 provided in all the second trenches 22 is electrically connected to the second gate electrode pad 105.

According to the second modified example of the second embodiment, similarly to the second embodiment, the reverse recovery loss (Err), the turn-on loss (Eon), and the conduction loss of the RC-IGBT are reduced. In addition, as the second gate trench in the diode region 102 increases, the forward voltage (Vr) at the time of conduction of the diode further decreases, and the conduction loss of the diode decreases.

### Third Modified Example

A semiconductor device according to a third modified example of the second embodiment is different from the semiconductor device according to the first embodiment in that the termination region further includes: a ninth semiconductor region of a first conductivity type, the ninth semiconductor region being provided in the semiconductor layer, the ninth semiconductor region being provided between the second semiconductor region and the second face, the ninth semiconductor region having a first conductivity type impurity concentration higher than a first conductivity type impurity concentration of the seventh semiconductor region, and the second electrode is in contact with the ninth semiconductor region.

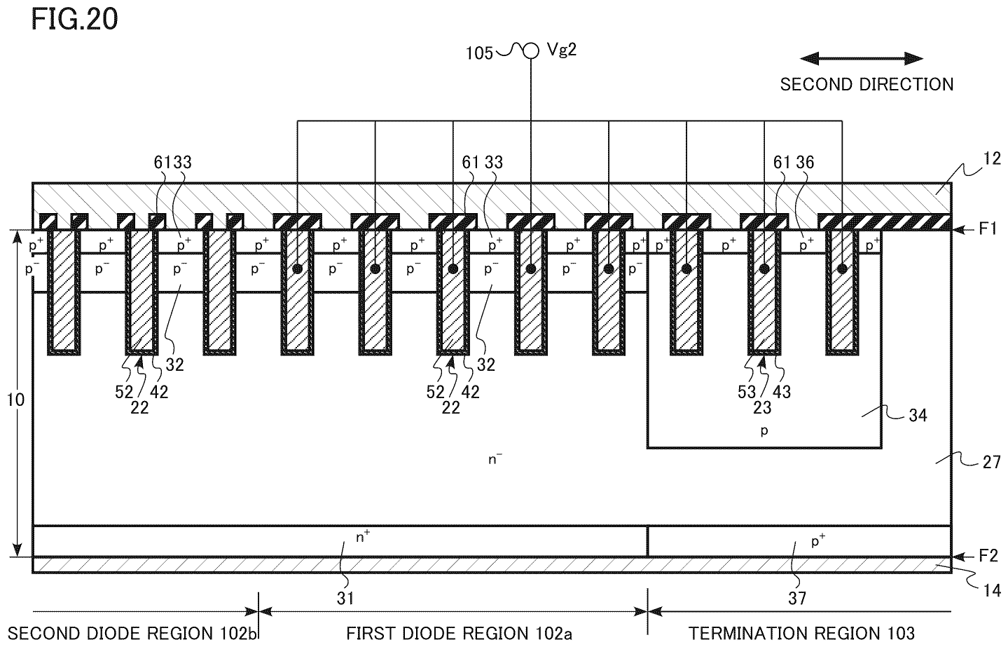

FIG. 20 is a schematic cross-sectional view of a part of a semiconductor device according to the third modified example of the second embodiment. FIG. 20 is a diagram corresponding to FIG. 15 of the second embodiment.

As illustrated in FIG. 20, the termination region 103 includes a p⁺ type termination back surface p region 37 (ninth semiconductor region) between the drift region 27 and the second face F2, and the termination back surface p region 37 is in contact with the lower electrode 14.

The p type impurity concentration of the termination back surface p region 37 is higher than the p type impurity concentration of the anode region 32, for example.

According to the third modified example of the second embodiment, similarly to the second embodiment, the reverse recovery loss (Err), the turn-on loss (Eon), and the conduction loss of the RC-IGBT are reduced. In addition, since the termination region 103 includes the termination back surface p region 37, hole injection from the parasitic diode of the termination region 103 is suppressed. Therefore, the reverse recovery loss (Err) and the turn-on loss (Eon) are further reduced.

As described above, according to the second embodiment and the modified examples, it is possible to realize a semiconductor device including an RC-IGBT having an IGBT and a diode and capable of reducing a loss.

### Third Embodiment

A semiconductor device according to a third embodiment includes: a transistor region; a diode region; and a termination region surrounding the transistor region and the diode region, the diode region being provided between the termination region and the transistor region. The transistor region includes: a semiconductor layer having a first face and a second face opposed to the first face; a first semiconductor region of a first conductivity type, the first semiconductor region being provided in the semiconductor layer; a second semiconductor region of a second conductivity type, the second semiconductor region being provided in the semiconductor layer and between the first semiconductor region and the first face; a third semiconductor region of a first conductivity type, the third semiconductor region being provided in the semiconductor layer and between the second semiconductor region and the first face; a fourth semiconductor region of a second conductivity type, the fourth semiconductor region being provided in the semiconductor layer and between the third semiconductor region and the first face; a plurality of first trenches provided on a side of the first face in the semiconductor layer, the first trenches extending in a first direction parallel to the first face, the first trenches being disposed repeatedly in a second direction perpendicular to the first direction and parallel to the first face, the first trenches being in contact with the second semiconductor region, the third semiconductor region, and the fourth semiconductor region; a first conductive layer provided in each of the first trenches; a first insulating film provided between the first conductive layer and the semiconductor layer; a first electrode provided on a side of the first face with respect to the semiconductor layer, the first electrode being in contact with the fourth semiconductor region; and a second electrode provided on a side of the second face with respect to the semiconductor layer, the second electrode being in contact with the first semiconductor region. The diode region includes: the semiconductor layer; the second semiconductor region; a fifth semiconductor region of a second conductivity type, the fifth semiconductor region being provided in the semiconductor layer, the fifth semiconductor region being provided between the second semiconductor region and the second face, the fifth semiconductor region having a second conductivity type impurity concentration higher than a second conductivity type impurity concentration of the second semiconductor region; a sixth semiconductor region of a first conductivity type provided in the semiconductor layer, the sixth semiconductor region being provided between the second semiconductor region and the first face; a plurality of second trenches provided on a side of the first face in the semiconductor layer, the second trenches extending in the first direction, the second trenches being disposed repeatedly in the second direction, the second trenches being in contact with the second semiconductor region and the sixth semiconductor region; a second conductive layer provided in each of the second trenches; a second insulating film provided between the second conductive layer and the semiconductor layer; the first electrode electrically connected to the sixth semiconductor region, and electrically connected to the second conductive layers provided in all of the second trenches; and the second electrode in contact with the fifth semiconductor region. The termination region includes: the semiconductor layer; the second semiconductor region; a seventh semiconductor region of a first conductivity type, the seventh semiconductor region being provided in the semiconductor layer, the seventh semiconductor region being provided between the second semiconductor region and the first face, the seventh semiconductor region being electrically connected to the first electrode; a third trench provided on a side of the first face in the semiconductor layer, the third trench being provided between the seventh semiconductor region and the first face, the third trench extending in the first direction, the third trench being in contact with the seventh semiconductor region; a third conductive layer provided in the third trench; a third insulating film provided between the third conductive layer and the semiconductor layer; the first electrode; the second electrode; a first electrode pad provided on a side of the first face with respect to the semiconductor layer, the first electrode pad being electrically connected to the first conductive layers that are provided in at least a part of the plurality of first trenches; and a second electrode pad provided on a side of the first face with respect to the semiconductor layer, the second electrode pad being electrically connected to the third conductive layer. The semiconductor device of the third embodiment is different from the semiconductor device of the second embodiment in that a second conductive layers provided in all the second trenches is electrically connected to the first electrode. Hereinafter, description of contents overlapping with the first embodiment or the second embodiment may be partially omitted.

The semiconductor device of the third embodiment is an RC-IGBT 300 in which an IGBT and a freewheeling diode are formed on the same semiconductor chip.

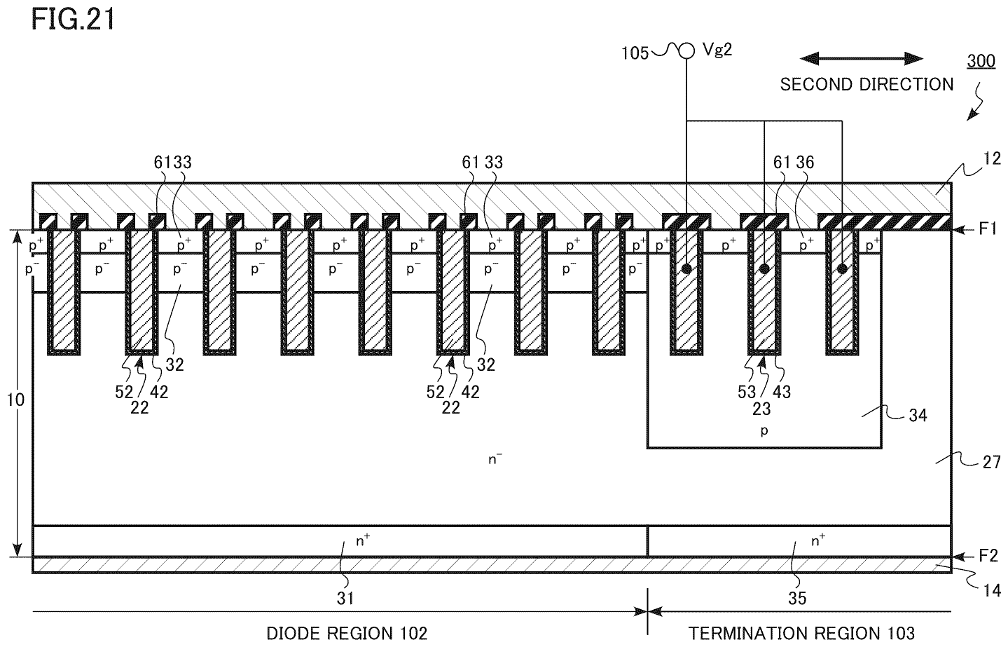

FIG. 21 is a schematic cross-sectional view of a part of the semiconductor device according to the third embodiment. FIG. 21 is a diagram corresponding to FIG. 15 of the second embodiment.

A plurality of third trenches 23 are provided in the semiconductor layer 10 in the termination region 103 of the RC-IGBT 300. As illustrated in FIG. 21, the third conductive layer 53 provided in all the third trenches 23 is electrically connected to the second gate electrode pad 105.

Therefore, discharge of holes from the drift region 27 to the upper electrode 12 via the guard ring region 34 is promoted. Therefore, the reverse recovery current (Irr) at the time of reverse recovery of the diode decreases, and the reverse recovery loss (Err) of the diode decreases.

By reducing the reverse recovery loss (Err) of the diode, the turn-on loss (Eon) in a case where the RC-IGBT 300 is used as a switching element of the inverter circuit is also further reduced.

Note that only the third conductive layer 53 provided in a part of the third trenches 23 may be electrically connected to the second gate electrode pad 105.

The number of the third trenches may be one.

The p type impurity concentration of the guard ring region 34 is preferably higher than the p type impurity concentration of the anode region 32. Since the p type impurity concentration of the guard ring region 34 is high, discharge of holes via the guard ring region 34 is further promoted, and the reverse recovery loss (Err) of the diode is further reduced.

### Modified Example

A semiconductor device according to a modified example of the third embodiment is different from the semiconductor device according to the third embodiment in that the termination region further includes: a ninth semiconductor region of a first conductivity type, the ninth semiconductor region being provided in the semiconductor layer, the ninth semiconductor region being provided between the second semiconductor region and the second face, the ninth semiconductor region having a first conductivity type impurity concentration higher than a first conductivity type impurity concentration of the seventh semiconductor region, and the second electrode is in contact with the ninth semiconductor region.

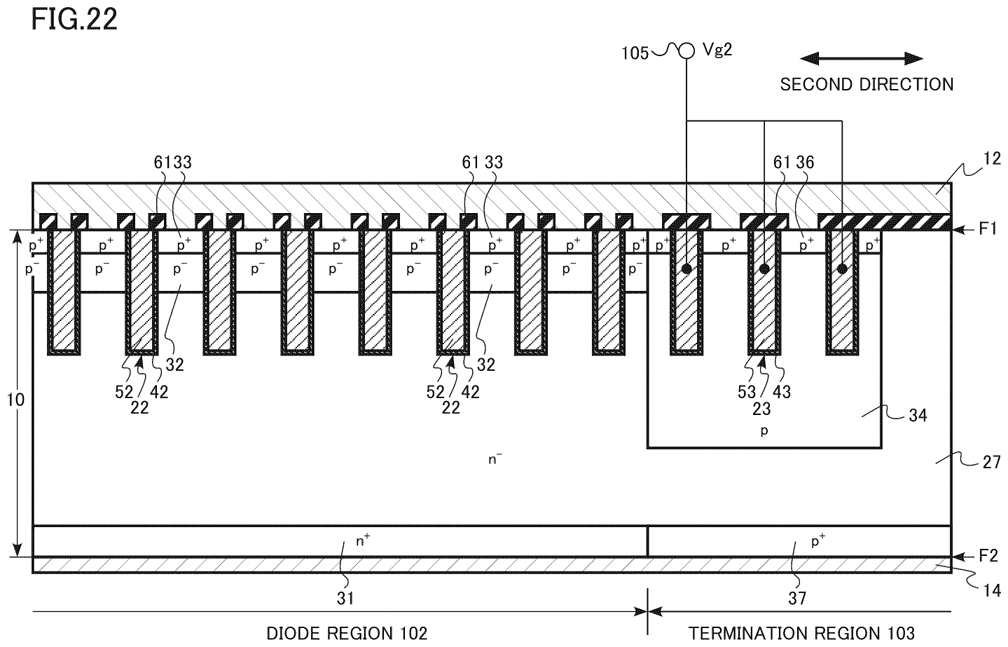

FIG. 22 is a schematic cross-sectional view of a part of the semiconductor device according to the third embodiment. FIG. 22 is a diagram corresponding to FIG. 21 of the third embodiment.

As illustrated in FIG. 22, the termination region 103 includes a p⁺ type termination back surface p region 37 (ninth semiconductor region) between the drift region 27 and the second face F2, and the termination back surface p region 37 is in contact with the lower electrode 14.

The p type impurity concentration of the termination back surface p region 37 is higher than the p type impurity concentration of the anode region 32, for example.

As described above, according to the third embodiment and the modified examples, it is possible to realize a semiconductor device including an RC-IGBT having an IGBT and a diode and capable of reducing a loss.

In the first to third embodiments, the case where the semiconductor layer is single crystal silicon has been described as an example, but the semiconductor layer is not limited to single crystal silicon. For example, other single crystal semiconductors such as single crystal silicon carbide may be used.

In the first to third embodiments, the case where the first conductivity type is p type and the second conductivity type is n type has been described as an example, but the first conductivity type may be n type and the second conductivity type may be p type.

In the first to third embodiments, it is also possible to adopt so-called trench contact in which the upper electrode 12 is embedded in a trench provided in the semiconductor layer 10.

In the first to third embodiments, it is also possible to perform carrier lifetime control.

While certain embodiments have been described, these embodiments have been presented by way of example only, and are not intended to limit the scope of the inventions.

Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a transistor region;
a diode region; and
a termination region surrounding the transistor region and the diode region, the diode region being provided between the termination region and the transistor region, wherein
the transistor region includes:
a semiconductor layer having a first face and a second face opposed to the first face;
a first semiconductor region of a first conductivity type, the first semiconductor region being provided in the semiconductor layer;
a second semiconductor region of a second conductivity type, the second semiconductor region being provided in the semiconductor layer and between the first semiconductor region and the first face;
a third semiconductor region of a first conductivity type, the third semiconductor region being provided in the semiconductor layer and between the second semiconductor region and the first face;
a fourth semiconductor region of a second conductivity type, the fourth semiconductor region being provided in the semiconductor layer and between the third semiconductor region and the first face;
a plurality of first trenches provided on a side of the first face in the semiconductor layer, the first trenches extending in a first direction parallel to the first face, the first trenches being disposed repeatedly in a second direction perpendicular to the first direction and parallel to the first face, the first trenches being in contact with the second semiconductor region, the third semiconductor region, and the fourth semiconductor region;
a first conductive layer provided in each of the first trenches;
a first insulating film provided between the first conductive layer and the semiconductor layer;
a first electrode provided on a side of the first face with respect to the semiconductor layer, the first electrode being in contact with the fourth semiconductor region; and
a second electrode provided on a side of the second face with respect to the semiconductor layer, the second electrode being in contact with the first semiconductor region,
the diode region includes:
the semiconductor layer;
the second semiconductor region;
a fifth semiconductor region of a second conductivity type, the fifth semiconductor region being provided in the semiconductor layer, the fifth semiconductor region being provided between the second semiconductor region and the second face, the fifth semiconductor region having a second conductivity type impurity concentration higher than a second conductivity type impurity concentration of the second semiconductor region;
a sixth semiconductor region of a first conductivity type provided in the semiconductor layer, the sixth semiconductor region being provided between the second semiconductor region and the first face;
a plurality of second trenches provided on a side of the first face in the semiconductor layer, the second trenches extending in the first direction, the second trenches being disposed repeatedly in the second direction, the second trenches being in contact with the second semiconductor region and the sixth semiconductor region;
a second conductive layer provided in each of the second trenches;
a second insulating film provided between the second conductive layer and the semiconductor layer;
the first electrode electrically connected to the sixth semiconductor region; and
the second electrode in contact with the fifth semiconductor region, and
the termination region includes:
the semiconductor layer;
the second semiconductor region;
a seventh semiconductor region of a first conductivity type, the seventh semiconductor region being provided in the semiconductor layer, the seventh semiconductor region being provided between the second semiconductor region and the first face, the seventh semiconductor region being electrically connected to the first electrode;
at least one third trench provided on a side of the first face in the semiconductor layer, the at least one third trench being provided between the seventh semiconductor region and the first face, the at least one third trench extending in the first direction, the at least one third trench being in contact with the seventh semiconductor region;
a third conductive layer provided in each of the at least one third trench;
a third insulating film provided between the third conductive layer and the semiconductor layer;
the first electrode;
the second electrode;
a first electrode pad provided on a side of the first face with respect to the semiconductor layer, the first electrode pad being electrically connected to the first conductive layer provided in each of at least a part of the plurality of first trenches; and
a second electrode pad provided on a side of the first face with respect to the semiconductor layer, the second electrode pad being electrically connected to the second conductive layer provided in a second trench closest to the at least one third trench among the plurality of second trenches.

2. The semiconductor device according to claim 1, wherein
the termination region further includes: an eighth semiconductor region of a second conductivity type, the eighth semiconductor region being provided in the semiconductor layer, the eighth semiconductor region being provided between the second semiconductor region and the second face, the eighth semiconductor region having a second conductivity type impurity concentration higher than a second conductivity type impurity concentration of the second semiconductor region, and
the second electrode is in contact with the eighth semiconductor region.

3. The semiconductor device according to claim 1, wherein the second conductive layers provided in a part of the second trenches are electrically connected to the first electrode.

4. The semiconductor device according to claim 1, wherein
the diode region includes: a first region; and a second region provided between the first region and the transistor region in the second direction,
the semiconductor layer in the first region includes the second trenches including the second trench closest to the at least one third trench,
the semiconductor layer in the second region includes the second trenches, and
a ratio of a number of the second trenches in which the second conductive layer electrically connected to the second electrode pad is provided among the second trenches in the first region to a number of the second trenches included in the first region is larger than a ratio of a number of the second trenches in which the second conductive layer electrically connected to the second electrode pad is provided among the second trenches in the second region to a number of the second trenches included in the second region.

5. The semiconductor device according to claim 1, wherein the second conductive layer provided in all of the second trenches are electrically connected to the second electrode pad.

6. The semiconductor device according to claim 1, wherein a distance between a second trench most distant from the seventh semiconductor region in the second direction among the second trenches provided with the second conductive layer electrically connected to the second electrode pad and the seventh semiconductor region is equal to or more than a thickness in a direction from the first face of the semiconductor layer toward the second face.

7. The semiconductor device according to claim 1, wherein the third conductive layer is electrically connected to the second electrode pad.

8. The semiconductor device according to claim 1, wherein a first conductivity type impurity concentration of the seventh semiconductor region is higher than a first conductivity type impurity concentration of the sixth semiconductor region.

9. The semiconductor device according to claim 1, wherein the at least one third trench is a plurality of third trenches, the third trenches are disposed repeatedly in the second direction, and the third conductive layer in each of the third trenches is electrically connected to the second electrode pad.

10. The semiconductor device according to claim 1, wherein the seventh semiconductor region surrounds the transistor region and the diode region.

11. The semiconductor device according to claim 1, wherein ends of the second trenches in the first direction are in contact with the seventh semiconductor region.

12. The semiconductor device according to claim 1, wherein the first conductive layer provided in another part of the first trenches are electrically connected to the first electrode.

13. The semiconductor device according to claim 1, wherein a depth of the seventh semiconductor region is deeper than a depth of the at least one third trench.

14. A semiconductor device comprising:
a transistor region;
a diode region; and
a termination region surrounding the transistor region and the diode region, the diode region being provided between the termination region and the transistor region, wherein
the transistor region includes:
a semiconductor layer having a first face and a second face opposed to the first face;
a first semiconductor region of a first conductivity type, the first semiconductor region being provided in the semiconductor layer;
a second semiconductor region of a second conductivity type, the second semiconductor region being provided in the semiconductor layer and between the first semiconductor region and the first face;
a third semiconductor region of a first conductivity type, the third semiconductor region being provided in the semiconductor layer and between the second semiconductor region and the first face;
a fourth semiconductor region of a second conductivity type, the fourth semiconductor region being provided in the semiconductor layer and between the third semiconductor region and the first face;
a plurality of first trenches provided on a side of the first face in the semiconductor layer, the first trenches extending in a first direction parallel to the first face, the first trenches being disposed repeatedly in a second direction perpendicular to the first direction and parallel to the first face, the first trenches being in contact with the second semiconductor region, the third semiconductor region, and the fourth semiconductor region;
a first conductive layer provided in each of the first trenches;
a first insulating film provided between the first conductive layer and the semiconductor layer;
a first electrode provided on a side of the first face with respect to the semiconductor layer, the first electrode being in contact with the fourth semiconductor region; and
a second electrode provided on a side of the second face with respect to the semiconductor layer, the second electrode being in contact with the first semiconductor region,
the diode region includes:
the semiconductor layer;
the second semiconductor region;
a fifth semiconductor region of a second conductivity type, the fifth semiconductor region being provided in the semiconductor layer, the fifth semiconductor region being provided between the second semiconductor region and the second face, the fifth semiconductor region having a second conductivity type impurity concentration higher than a second conductivity type impurity concentration of the second semiconductor region;
a sixth semiconductor region of a first conductivity type provided in the semiconductor layer, the sixth semiconductor region being provided between the second semiconductor region and the first face;
a plurality of second trenches provided on a side of the first face in the semiconductor layer, the second trenches extending in the first direction, the second trenches being disposed repeatedly in the second direction, the second trenches being in contact with the second semiconductor region and the sixth semiconductor region;
a second conductive layer provided in each of the second trenches;
a second insulating film provided between the second conductive layer and the semiconductor layer;
the first electrode electrically connected to the sixth semiconductor region, and electrically connected to the second conductive layer provided in all of the second trenches; and
the second electrode in contact with the fifth semiconductor region, and wherein
the termination region includes:
the semiconductor layer;
the second semiconductor region;
a seventh semiconductor region of a first conductivity type, the seventh semiconductor region being provided in the semiconductor layer, the seventh semiconductor region being provided between the second semiconductor region and the first face, the seventh semiconductor region being electrically connected to the first electrode;
at least one third trench provided on a side of the first face in the semiconductor layer, the at least one third trench being provided between the seventh semiconductor region and the first face, the at least one third trench extending in the first direction, the at least one third trench being in contact with the seventh semiconductor region;
a third conductive layer provided in each of the at least one third trench;
a third insulating film provided between the third conductive layer and the semiconductor layer;
the first electrode;
the second electrode;
a first electrode pad provided on a side of the first face with respect to the semiconductor layer, the first electrode pad being electrically connected to the first conductive layer provided in each of at least a part of the plurality of first trenches; and
a second electrode pad provided on a side of the first face with respect to the semiconductor layer, the second electrode pad being electrically connected to the third conductive layer.

15. The semiconductor device according to claim 14, wherein
the termination region further includes: an eighth semiconductor region of a second conductivity type, the eighth semiconductor region being provided in the semiconductor layer, the eighth semiconductor region being provided between the second semiconductor region and the second face, the eighth semiconductor region having a second conductivity type impurity concentration higher than a second conductivity type impurity concentration of the second semiconductor region, and
the second electrode is in contact with the eighth semiconductor region.

16. The semiconductor device according to claim 14, wherein a first conductivity type impurity concentration of the seventh semiconductor region is higher than a first conductivity type impurity concentration of the sixth semiconductor region.

17. The semiconductor device according to claim 14, wherein a depth of the seventh semiconductor region is deeper than a depth of the at least one third trench.
